(19) United States
(12) Patent Application Publication
(10) Pub. No.: US 2022/0263033 A1
(43) Pub. Date: Aug. 18, 2022

(54) ETCHING PROCESS

(71) Applicant: OXFORD UNIVERSITY INNOVATION LIMITED, Oxford (GB)

(72) Inventors: Henry James Snaith, Oxford (GB); Yasser Hassan, Oxford (GB); Ashley Marshal, Oxford (GB); Suer Zhou, Oxford (GB)

(21) Appl. No.: 17/672,977

(22) Filed: Feb. 16, 2022

(30) Foreign Application Priority Data
Feb. 16, 2021 (GB) 2102141.5

(51) Int. Cl. H01L 51/00; C09K 11/06; C09K 13/00; C07F 7/24

(52) U.S. Cl. CPC H01L 51/0077; C09K 11/06; C09K 13/00; H01L 51/5088; H01L 51/0017; C09K 2211/10; C07F 7/24

(57) ABSTRACT

The invention relates to a process for chemically etching the surface of a metal halide perovskite, the process comprising treating the metal halide perovskite with one or more multidentate ligands, wherein the one or more multidentate ligands comprise an organic compound or a salt thereof, which organic compound comprises three or more binding groups. A chemically etched metal halide perovskite, a process for producing a semiconductor device, a composition and a semiconductor device are also described.

### FIELD OF THE INVENTION

The invention relates to a process for chemically etching the surface of a metal halide perovskite. Also related to the invention is a composition, a semiconductor device and a process for producing a semiconductor device.

### BACKGROUND OF THE INVENTION

Metal halide perovskites are promising semiconductors for light-emitting applications, owing to their bright, bandgap tuneable, and high colour purity luminescence. Close to unity photoluminescence quantum yields have been achieved for perovskite nanocrystals across a broad range of emission colours, and light-emitting diodes with external quantum efficiencies exceeding 20%, which approach commercial OLEDs, have been demonstrated in both the Infrared and green emission channels.

The bandgap of metal halide perovskites can be tuned by several means, such as quantum confinement in nanocrystals (NCs) and two-dimensional perovskites, or by varying the halide composition in the ABX₃ perovskite stoichiometry, where A is organic ammonium or alkali metal cation, B is a group IV metal cation, typically lead, and X are halide anions. A red emission wavelength between 615 and 640 nm, required for displays, can be obtained with photoluminescence quantum yield (PLQY) approaching unity using NCs with a mixture of iodide and bromide. However, these NCs are susceptible to halide segregation upon photoexcitation and the application of electrical bias. Despite much effort, colour-stable red electroluminescence (EL) from mixed halide perovskite NCs has not yet been.

Halide segregation is likely to occur via diffusion of vacancy and interstitial defects. In mixed-halide perovskite films measured experimentally and neat-iodide systems studied computationally, halide defects appear to migrate to grain boundaries or crystal surfaces. For polycrystalline films, improvements in bandgap stability and device efficiency have been achieved by passivating grain boundaries with organic compounds such as alkali metal halides or larger organic ammonium cations. For NCs, control of surface defects is particularly critical due to the high surface area to volume ratio and reports that halide segregation can occur both within (intra) and between (inter) NCs.

WO 2015/092397 A1 describes passivation of metal halide perovskites with organic compounds that bind to the surface of the perovskite. The use of organic compounds to bind to surface defects in metal halide perovskites is also described in: Pan et al, J Am Chem Soc 2018 140 (2), 562-565; Yin et al, ACS Energy Lett 2021, 6, 477-484; Zhang, J Phys Chem Lett 2019, 10, 5055-5063; and Li et al, Nature Chemistry 2015, 7, 703-711.

There remains a need to develop approaches to reducing halide segregation and increasing luminescence efficiency in metal halide perovskite NCs.

### SUMMARY OF THE INVENTION

The inventors have found that it is possible to reduce defects on the surface of metal halide perovskites by selectively chemically etching metal atoms from the perovskite surface using a multidentate ligand. A key function of the multidentate ligand treatment is to “clean” the metal halide perovskite surface through the removal of metal atoms (and in particular lead atoms). This selective chemical etching inhibits halide-segregation, for instance by suppressing halide Frenkel defect formation. As a result, colour stable emission from the metal halide perovskite with high electroluminescence external quantum efficiencies can be achieved.

The invention accordingly provides a process for chemically etching the surface of a metal halide perovskite, the process comprising treating the metal halide perovskite with one or more multidentate ligands, wherein the one or more multidentate ligands comprise an organic compound or a salt thereof, which organic compound comprises three or more binding groups.

The invention also provides a chemically etched metal halide perovskite obtainable by the process for chemically etching the surface of a metal halide perovskite.

Further provided is a process for producing a semiconductor device comprising a metal halide perovskite, the process comprising the process for chemically etching the surface of a metal halide perovskite.

The invention also provides a composition comprising a metal halide perovskite and one or more multidentate ligands, wherein the one or more multidentate ligands comprise an organic compound or a salt thereof, which organic compound comprises three or more binding groups, which three or more binding groups comprise two or more carboxylic acid groups. A semiconductor device comprising the composition is also provided.

### BRIEF DESCRIPTION OF THE FIGURES

FIG. 1 shows an illustration of perovskite nanocrystal (NC) synthesis. a, Synthesis and ligand treatment steps: (i) Dissolution of perovskite precursors in acetonitrile (ACN) and methylamine (MA), (ii) NC synthesis by modified ligand assisted re-precipitation (LARP) method, and (iii) post-synthetic ligand treatment. b, chemical structures of ligands used.

FIG. 2 shows the impact of ligand treatment on the solution photoluminescence and NC structural properties. a, Absorption and PL spectra of as-synthesised MAPb(I₁₋ₓBrₓ)₃ NCs in solution. b, PL spectra of NC films following post-synthetic treatment with GL, EDTA, and EDTA+GL (E+G). c, Excitation fluence dependence of PLQE of NC thin films before and after ligand treatment, measured in an integrating sphere. d,e, High-resolution transmission electron micrograph (HR-TEM) image for NCs before and after ligand treatment with E+G, respectively. f, XRD for the NCs films before and after ligand treatment. g,h: Decay associated difference spectra from a global fit of TAS measurements of neat- and E+G-capped NCs, respectively. Solid and dashed lines are spectra before and after 30 s of exposure to a 7.1 W cm⁻² 405 nm CW laser. B, G, and R traces correspond to decay components with time constants of ˜400 fs, ˜14 ps, and ˜280 ps, respectively. Arrows indicate the red edge of the spectra, where changes in the bandgap of the material would result in changes to the bleaching of the sample due to band filling.

FIG. 3 shows device characterisation of mixed halide MAPb(I₁₋ₓBrₓ)₃ NC-LEDs: a, Schematic illustration of MAPb(I₁₋ₓBrₓ)₃ NC-LED architecture and scanning electron microscopy (SEM) image showing the cross section of a device; thickness of each layer is confirmed by SEM image: PEDOT:PSS/Poly-TPD/TFB HTLs (30 nm), NC emission layer (20 nm), TPBi ETL (70 nm), LiF/Al electrode (80 nm). b, Energy band diagram of the materials employed in these LEDs. Operational characteristics for LEDs incorporating neat and E+G ligand treated NC layers: c, Current density-voltage and luminance(L)-voltage curves, d, EQE-current density curves, e, device performance parameters of best-performing LEDs (LE is luminous efficiency). f, EL spectra at different time intervals for LEDs held at a constant current density of 1.5 mA cm⁻² g, EL spectra at different current densities (mAcm⁻²).

FIG. 4 shows characterisation of ligand-NC surface interactions using NMR spectroscopy: a: Molecular structure of EDTA and GL. Peaks a and b are characteristic of CH₂ as labelled in the molecular structure of EDTA while peaks α, β and γ are characteristic of CH₂ in GL. b: ¹³C solid-state NMR spectra of neat and ligand (GL, EDTA, E+G) treated NCs. Insets show ligand structure. c: Solution ¹H NMR spectra of E+G with and without PbI₂ in d-DMSO solutions. d: Proposed molecular interactions of GL and EDTA with Pb²⁺ atoms on the NC surface.

FIG. 5 shows optimised structures of two interacting surface adsorbed a, GL, b, EDTA, and c, one GL and one EDTA molecule, along with calculated total biding energies (E_{b}) and their intermolecular contribution (ΔEᵢₙₜₑᵣ) in eV calculated with respect to the isolated surface adsorbed molecules (E_{b}=1.85 and 1.60 eV for GL and EDTA, respectively). d, Optimised structure of an iodine Frenkel defect pair—defective sites highlighted by red and blue circles—in the presence of adsorbed GL+EDTA along with the increase of defect formation energy compared to the unpassivated surface (ΔE_{Frenkel}, in eV).

FIG. 6 shows PLQE of FACs films treated with EDTA for different lengths of time.

FIG. 7 shows PLQE of polycrystalline perovskite films rinsed with EDTA solution in different solvents.

### DETAILED DESCRIPTION OF THE INVENTION

The term “perovskite” as used herein refers to a material with a crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0, 0, 0), the B cations are at (½, ½, ½) and the X anions are at (½, ½, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄-type structure comprises a layer of perovskite material. The skilled person will appreciate that a perovskite material can be represented by the formula [A][B][X]₃, wherein [A] is at least one cation, [B] is at least one cation and [X] is at least one anion. When the perovskite comprises more than one A cation, the different A cations may be distributed over the A sites in an ordered or disordered way. When the perovskite comprises more than one B cation, the different B cations may be distributed over the B sites in an ordered or disordered way. When the perovskite comprises more than one X anion, the different X anions may be distributed over the X sites in an ordered or disordered way. The symmetry of a perovskite comprising more than one A cation, more than one B cation or more than one X anion, will be lower than that of CaTiO₃. For layered perovskites the stoichiometry can change between the A, B and X ions. As an example, the [A]₂[B][X]₄ structure can be adopted if the A cation has a too large an ionic radius to fit within the 3D perovskite structure. The term “perovskite” also includes A/M/X materials adopting a Ruddlesden-Popper phase. Ruddlesden-Popper phase refers to a perovskite with a mixture of layered and 3D components. Such perovskites can adopt the crystal structure, Aₙ₋₁A′₂MₙX₃ₙ₊₁, where A and A′ are different cations and n is an integer from 1 to 8, or from 2 to 6. The term “mixed 2D and 3D” perovskite is used to refer to a perovskite film within which there exists both regions, or domains, of AMX₃ and Aₙ₋₁A′₂MₙX₃ₙ₊₁ perovskite phases.

The term “metal halide perovskite” as used herein refers to a perovskite, the formula of which contains at least one metal cation and at least one halide anion.

The term “monocation”, as used herein, refers to any cation with a single positive charge, i.e. a cation of formula A⁺ where A is any moiety, for instance a metal atom or an organic moiety. The term “dication”, as used herein, refers to any cation with a double positive charge, i.e. a cation of formula A²⁺ where A is any moiety, for instance a metal atom or an organic moiety. The term “trication”, as used herein, refers to any cation with a double positive charge, i.e. a cation of formula A³⁺ where A is any moiety, for instance a metal atom or an organic moiety. The term “tetracation”, as used herein, refers to any cation with a quadruple positive charge, i.e. a cation of formula A⁴⁺ where A is any moiety, for instance a metal atom.

The term “alkyl” as used herein refers to a linear or branched chain saturated hydrocarbon radical. An alkyl group may be a C₁₋₂₀ alkyl group, a C₁₋₁₄ alkyl group, a C₁₋₁₀ alkyl group, a C₁₋₆ alkyl group or a C₁₋₄ alkyl group. Examples of a C₁₋₁₀ alkyl group are methyl, ethyl, propyl, butyl, pentyl, hexyl, heptyl, octyl, nonyl or decyl. Examples of C₁₋₆ alkyl groups are methyl, ethyl, propyl, butyl, pentyl or hexyl. Examples of C₁₋₄ alkyl groups are methyl, ethyl, i-propyl, n-propyl, t-butyl, s-butyl or n-butyl. If the term “alkyl” is used without a prefix specifying the number of carbons anywhere herein, it has from 1 to 6 carbons (and this also applies to any other organic group referred to herein).

The term “cycloalkyl” as used herein refers to a saturated or partially unsaturated cyclic hydrocarbon radical. A cycloalkyl group may be a C₃₋₁₀ cycloalkyl group, a C₃₋₈ cycloalkyl group or a C₃₋₆ cycloalkyl group. Examples of a C₃₋₈ cycloalkyl group include cyclopropyl, cyclobutyl, cyclopentyl, cyclohexyl, cyclohexenyl, cyclohex-1,3-dienyl, cycloheptyl and cyclooctyl. Examples of a C₃₋₆ cycloalkyl group include cyclopropyl, cyclobutyl, cyclopentyl and cyclohexyl.

The term “alkenyl” as used herein refers to a linear or branched chain hydrocarbon radical comprising one or more double bonds. An alkenyl group may be a C₂₋₂₀ alkenyl group, a C₂₋₁₄ alkenyl group, a C₂₋₁₀ alkenyl group, a C₂₋₆ alkenyl group or a C₂₋₄ alkenyl group. Examples of a C₂₋₁₀ alkenyl group are ethenyl (vinyl), propenyl, butenyl, pentenyl, hexenyl, heptenyl, octenyl, nonenyl and decenyl. Examples of C₂₋₆ alkenyl groups are ethenyl, propenyl, butenyl, pentenyl and hexenyl. Examples of C₂₋₄ alkenyl groups are ethenyl, i-propenyl, n-propenyl, s-butenyl and n-butenyl. Alkenyl groups typically comprise one or two double bonds.

The term “alkynyl” as used herein refers to a linear or branched chain hydrocarbon radical comprising one or more triple bonds. An alkynyl group may be a C₂₋₂₀ alkynyl group, a C₂₋₁₄ alkynyl group, a C₂₋₁₀ alkynyl group, a C₂₋₆ alkynyl group or a C₂₋₄ alkynyl group. Examples of a C₂₋₁₀ alkynyl group are ethynyl, propynyl, butynyl, pentynyl, hexynyl, heptynyl, octynyl, nonynyl and decynyl. Examples of C₁₋₆ alkynyl groups are ethynyl, propynyl, butynyl, pentynyl and hexynyl. Alkynyl groups typically comprise one or two triple bonds.

The term “aryl” as used herein refers to a monocyclic, bicyclic or polycyclic aromatic ring which contains from 6 to 14 carbon atoms, typically from 6 to 10 carbon atoms, in the ring portion. Examples include phenyl, naphthyl, indenyl, indanyl, anthrecenyl and pyrenyl groups. The term “aryl group” as used herein includes heteroaryl groups. The term “heteroaryl” as used herein refers to monocyclic or bicyclic heteroaromatic rings which typically contains from six to ten atoms in the ring portion including one or more heteroatoms. A heteroaryl group is generally a 5- or 6-membered ring, containing at least one heteroatom selected from O, S, N, P, Se and Si. It may contain, for example, one, two or three heteroatoms. Examples of heteroaryl groups include pyridyl, pyrazinyl, pyrimidinyl, pyridazinyl, furanyl, thienyl, pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl.

The term “substituted” as used herein in the context of substituted organic groups refers to an organic group which bears one or more substituents selected from C₁₋₁₀ alkyl, aryl (as defined herein), cyano, amino, nitro, C₁₋₁₀ alkylamino, di(C₁₋₁₀)alkylamino, arylamino, diarylamino, aryl(C₁₋₁₀)alkylamino, amido, acylamido, hydroxy, oxo, halo, carboxy, ester, acyl, acyloxy, C₁₋₁₀ alkoxy, aryloxy, halo(C₁₋₁₀)alkyl, sulfonic acid, thiol, C₁₋₁₀ alkylthio, arylthio, sulfonyl, phosphoric acid, phosphate ester, phosphonic acid and phosphonate ester. Examples of substituted alkyl groups include haloalkyl, perhaloalkyl, hydroxyalkyl, aminoalkyl, alkoxyalkyl and alkaryl groups. When a group is substituted, it may bear 1, 2 or 3 substituents. For instance, a substituted group may have 1 or 2 substituents.

The term “semiconductor device” as used herein refers to a device comprising a functional component which comprises a semiconductor material. This term may be understood to be synonymous with the term “semiconducting device”. Examples of semiconductor devices include a photovoltaic device, a solar cell, a photo detector, a photodiode, a photosensor, a chromogenic device, a transistor, a light-sensitive transistor, a phototransistor, a solid state triode, a battery, a battery electrode, a capacitor, a super-capacitor, a light-emitting device, a laser or a light-emitting diode. The term “optoelectronic device” as used herein refers to devices which source, control or detect light. Light is understood to include any electromagnetic radiation. Examples of optoelectronic devices include photovoltaic devices, photodiodes (including solar cells), phototransistors, photomultipliers, photoresistors, lasers and light emitting diodes.

The term “consisting essentially of” refers to a composition comprising the components of which it consists essentially as well as other components, provided that the other components do not materially affect the essential characteristics of the composition. Typically, a composition consisting essentially of certain components will comprise greater than or equal to 95 wt % of those components or greater than or equal to 99 wt % of those components.

The process of the invention is a process for chemically etching the surface of a metal halide perovskite. Etching of a surface typically comprises removal of material from the surface. Chemical etching typically comprises removal of material from the surface using a chemical compound which acts as an etchant. The one or more multidentate ligands typically act as the chemical etchant in the process of the invention.

The process of the invention is typically a process for selectively etching the surface of a metal halide perovskite, and in particular a process for selectively etching metal atoms from the surface of a metal halide perovskite. The one or more multidentate ligands may bind to metal atoms at the surface of the metal halide perovskite and remove the metal atoms from the surface. As a result, the molar concentration of the metal in the metal halide perovskite is typically reduced following the process of the invention. For instance, the molar ratio of metal ions to halide ions in the metal halide perovskite following chemical etching may be lower than the molar ratio of metal ions to halide ions in the metal halide perovskite prior to the chemical etching process.

The process typically comprises treating a composition comprising the metal halide perovskite with the one or more multidentate ligands. The composition comprising the metal halide perovskite comprises the metal halide perovskite and optionally one or more additional components. For instance, as discussed further below, the composition comprising the metal halide perovskite may comprise the metal halide perovskite and a solvent, or the composition comprising the metal halide perovskite may comprise the metal halide perovskite and one or more passivating agents. The composition comprising the metal halide perovskite typically comprises the metal halide perovskite in solid form, for instance as particles of the metal halide perovskite or a layer of the metal halide perovskite.

The process may further comprising producing a by-product composition comprising the one or multidentate ligands and metal atoms which have been chemically etched from the surface of the metal halide perovskite. The selective etching of metal atoms by the process of the invention means that the stoichiometry of the metal in the by-product composition is typically greater than stoichiometry of the metal in the metal halide perovskite composition. For instance, if the composition comprising the metal halide perovskite has the formula AMX₃ where M is a metal dication, A is a first cation and X is a halide, then the molar ratio of M to A in the by-product composition may be greater than 1:1, for instance from 1.000001:1 to 1.5:1, or from 1.0001:1 to 1.1:1. In contrast, for a chemical etching process that does not selectively etch metal atoms (for instance etching using a compound which does not differentiate between different ions in the metal halide perovskite), the molar ratio of M to A would be about 1:1. The process may further comprising isolating the by-product composition.

It is believed that by chemically etching metal atoms from the surface of the metal halide perovskite, the number of defects at the surface of the metal halide perovskite in the composition comprising the metal halide perovskite can be reduced. The concentration of under-coordinated metal ions at the surface of the metal halide perovskite may be reduced following the chemical etching process. The one or more multidentate ligands can complex or chelate metal ions at the surface of the metal halide perovskite and remove the complexed or chelated metal ions. The process typically produces multidentate complexes of the metal ions from the metal halide perovskite, for instance tridentate, tetradentate, pentadentate or hexadentate complexes of the metal ions.

The metal halide perovskite often comprises lead (e.g. Pb²⁺). When the metal halide perovskite comprises lead, the process is typically a process for selectively chemically etching lead atoms (or ions) from the surface of the metal halide perovskite. The one or more multidentate ligands typically remove lead atoms or ions (for instance under-coordinated lead atoms or ions) from the surface of the metal halide perovskite. The one or multidentate ligands can remove the lead atoms or ions from the surface of the metal halide perovskite by complexing (or chelating) Pb²⁺, and the complexed Pb²⁺ can be removed, for instance by rinsing with a rinsing solvent. The metal halide perovskite may additionally or alternatively comprise a different metal, for instance tin (Sn²⁺). In that case, the one or more multidentate ligands can complex the Sn²⁺ and remove Sn²⁺ from the surface of the metal halide perovskite.

The one or more multidentate ligands comprise an organic compound or a salt thereof, which organic compound comprises three or more binding groups. The organic compound may comprise four or more, or five or more, binding groups. The one or more multidentate ligands may be one or more organic compounds or salts thereof, which organic compounds comprise three or more binding groups. The one or more multidentate ligands may be a single multidentate ligand which is an organic compound or a salt thereof, which organic compound comprises three or more binding groups. The one or more multidentate ligands may alternatively be two or more multidentate ligands, each of which is an organic compound or a salt thereof, which organic compound comprises three or more binding groups. The one or more multidentate ligands may additionally comprise one or more organic compounds comprising two or more binding groups.

Typically, the organic compound is not in salt form when it is initially contacted with the composition comprising the metal halide perovskite. If the organic compound is used in salt form to treat the composition comprising the metal halide perovskite, any suitable salt may be used including, for instance, alkali metal salts (e.g. sodium or potassium) or ammonium salts. The organic compound present in the one or more multidentate ligands is typically suitable for binding to Pb²⁺. The organic compound may have an affinity for binding to Pb²⁺ or may selectively bind to Pb²⁺. Typically the organic compound or salt thereof forms a complex with Pb²⁺ which has a stability constant which is greater than the complex which is formed with any other ion in the metal halide perovskite. Typically, the stability constant log K of the organic compound or salt thereof present in the one or more multidentate ligands with Pb²⁺ is greater than 5.0, greater than 8.0, greater than 10.0, greater than 12.5 or greater than 15.0. For instance, log K may be from 10.0 to 30.0. The one or more multidentate ligands may comprise two or more organic compounds as defined herein, which two or more organic compounds each have a log K of greater than 8.0 or greater than 10.0.

Log K typically corresponds to the stability constant of the formation [PbL], i.e. complexation of lead by one molecule of the organic compound present in the multidentate ligands. The stability constant is typically as measured under standard conditions, for instance in aqueous solution at an ionic strength of 0.1 M and a temperature of 25° C.

The organic compound present in the one or more multidentate ligands may alternatively or additionally be suitable for binding to Sn²⁺. The organic compound may have an affinity for binding to Sn²⁺ or may selectively bind to Sn²⁺. Typically the organic compound or salt thereof forms a complex with Sn²⁺ which has a stability constant which is greater than the complex which is formed with any other ion in the metal halide perovskite. Typically, the stability constant log K of the organic compound or salt thereof present in the one or more multidentate ligands with Sn²⁺ is greater than 5.0, greater than 8.0, greater than 10.0, greater than 12.5 or greater than 15.0. For instance, log K may be from 10.0 to 30.0.

The one or more multidentate ligands typically are not polymeric multidentate ligands. The organic compound present in the one or more multidentate ligands typically comprises from three to fifteen binding groups, or from three to eight binding groups. Typically, the organic compound has a molecular weight of no greater than 1000 gmol⁻¹, preferably no greater than 500 gmol⁻¹. For instance, the organic compound may have a molecular weight of from 100 gmol⁻¹ to 400 gmol⁻¹.

Typically, two or more of the three or more binding groups are carboxylic acid groups. For instance, the one or more multidentate ligands may comprise an organic compound or a salt thereof, which organic compound comprises two or more carboxylic acid groups. In some cases, the organic compound comprises three or more carboxylic acid groups, for instance from three to six carboxylic acid groups. The organic compound may comprise four or more carboxylic acid groups.

The organic compound may be in the form of a salt. Typically, however, the organic compound is not in salt form. For instance, the organic compound may comprise two or more carboxylic acid groups (—COOH) which are protonated prior to treatment of the metal halide perovskite. During the process (for instance on complexation of the metal ions in the metal halide perovskite) one or more of the carboxylic acid groups may be deprotonated.

The one or more multidentate ligands typically comprise an organic compound or a salt thereof, which organic compound comprises (a) two or more carboxylic acid groups and (b) one or more amine groups or one or more thiol groups.

The one or more multidentate ligands may comprise an organic compound which is an aminopolycarboxylic acid. For instance, the organic compound may comprises (a) two or more carboxylic acid groups and (b) one or more amine groups. The amine groups may be primary (—NH₂), secondary (>NH) or tertiary (>N—) amine groups. The organic compound may comprise (a) two or more carboxylic acid groups and (b) one or more tertiary amine groups. The organic compound may comprise (a) three or more carboxylic acid groups and (b) two or more tertiary amine groups. The carboxylic acid groups and amine groups are typically bonded to each other by alkylene groups (for instance methylene, ethylene or propylene) or alkylene glycol groups (for instance ethylene glycol).

The aminopolycarboxylic acid may be selected from ethylenediaminetetracetic acid (EDTA), iminodiacetic acid (IDA), N-methyliminodiacetic acid, 1,6-diaminohexanetetracetic acid, iminodisuccinic acid (IDS), nitrilotriacetic acid (NTA), diethylenetriaminepentaacetic acid (DTPA), ethylene glycol-bis(2-aminoethylether)-N,N,N′,N′-tetraacetic acid (EGTA), 1,2-bis(o-aminophenoxy)ethane-N,N,N′,N′-tetraacetic acid (BAPTA), (1,4,7-triazacyclononane-1,4,7-triyl)triacetic acid (NOTA), 1,4,7,10-tetraazacyclododecane-1,4,7,10-tetraacetic acid (DOTA), 1,2-bis(2-aminophenoxy)ethane-N,N,N′,N′-tetraacetic acid, trans-1,2-diaminocyclohexane-N,N,N′,N′-tetraacetic acid, 1,3-diamino-2-hydroxypropane-N,N,N′,N′-tetraacetic acid, 1,2-diaminopropane-N,N,N′,N′-tetraacetic acid, ethylenediamine-N,N′-diacetic acid, ethylenediaminetetrapropionic acid, N-(2-hydroxyethyl) ethylenediaminetriacetic acid, N-(2-hydroxyethyl)ethylenediamine-N,N′,N′-triacetic acid, N,N,N′,N′-tetrakis(2-hydroxyethyl)ethylenediamine, triethylenetetramine-N,N,N′,N″,N′″,N′″-hexaacetic acid, 1,3-diamino-2-propanol-N,N,N′,N′-tetraacetic acid, N-(2-hydroxyethyl)ethylenediamine-N,N′,N′-triacetic acid, trans-1,2-cyclohexanediaminetetraacetic acid, nicotianamine, ethylenediamine-N,N′-disuccinic acid (EDDS), ethylenediamine-N,N′-bis(2-hydroxyphenylacetic acid) (EDDHA) and methylglycinediacetic acid (MGDA).

The organic compound may be a peptide. For instance, the organic compound may comprise two or more amino acids bonded to each other (e.g. a dipeptide). The amino acids are typically selected from the twenty standard proteinogenic amino acids.

The organic compound may comprise (a) two or more carboxylic acid groups and (b) one or more thiol groups (—SH). The organic compound may for instance comprise two or more amino acids bonded to each, which two or more amino acids comprises cysteine.

The one or more multidentate ligands typically comprise one or more organic compounds selected from ethylenediaminetetracetic acid (EDTA), glutathione reduced (GL), glutathione oxidised, aspartic acid, iminodiacetic acid (IDA), N-methyliminodiacetic acid, 1,6-diaminohexanetetracetic acid, iminodisuccinic acid (IDS), nitrilotriacetic acid (NTA), diethylenetriaminepentaacetic acid (DTPA), ethylene glycol-bis(2-aminoethylether)-N,N,N′,N′-tetraacetic acid (EGTA), 1,2-bis(o-aminophenoxy)ethane-N,N,N′,N′-tetraacetic acid (BAPTA), (1,4,7-triazacyclononane-1,4,7-triyl)triacetic acid (NOTA), 1,4,7,10-tetraazacyclododecane-1,4,7,10-tetraacetic acid (DOTA), 1,2-bis(2-aminophenoxy)ethane-N,N,N′,N′-tetraacetic acid, trans-1,2-diaminocyclohexane-N,N,N′,N′-tetraacetic acid, 1,3-diamino-2-hydroxypropane-N,N,N′,N′-tetraacetic acid, 1,2-diaminopropane-N,N,N′,N′-tetraacetic acid, ethylenediamine-N,N′-diacetic acid, ethylenediaminetetrapropionic acid, N-(2-hydroxyethyl) ethylenediaminetriacetic acid, N-(2-hydroxyethyl)ethylenediamine-N,N′,N′-triacetic acid, N,N,N′,N′-tetrakis(2-hydroxyethyl)ethylenediamine, triethylenetetramine-N,N,N′,N″,N′″,N′″-hexaacetic acid, 1,3-diamino-2-propanol-N,N,N′,N′-tetraacetic acid, N-(2-hydroxyethyl)ethylenediamine-N,N′,N′-triacetic acid, trans-1,2-cyclohexanediaminetetraacetic acid, nicotianamine, ethylenediamine-N,N′-disuccinic acid (EDDS), ethylenediamine-N,N′-bis(2-hydroxyphenylacetic acid) (EDDHA), methylglycinediacetic acid (MGDA), dimercaprol, dimercaptosuccinic acid (DMSA) penicillamine (Pen), cysteine (Cys), desferrioxamine B (DFB), desferricoprogen (DFC), N,N′-bis[(6-carboxy-2-pyridyl)methyl]-4,13-diaza-18-crown-6, N-phenylthio-benzohydroxamic acid, alanyl-cysteine (AlaCys), cysteinyl-glycine (CysGly), a compound of formula HO(CH₃)NCO(CH₂)ₓCONH(CH₂)_{y}CON(CH₃)OH where x=2 or 3, y=2 to 5, and salts thereof.

Typically, the one or more multidentate ligands comprise one or more of ethylenediaminetetracetic acid (EDTA), diethylenetriaminepentaacetic acid (DTPA), ethylene glycol-bis(2-aminoethylether)-N,N,N′,N′-tetraacetic acid (EGTA), (1,4,7-triazacyclononane-1,4,7-triyl)triacetic acid (NOTA), 1,4,7,10-tetraazacyclododecane-1,4,7,10-tetraacetic acid (DOTA), glutathione reduced (GL), dimercaprol or dimercaptosuccinic acid (DMSA).

The one or more multidentate ligands may comprise one or more organic compounds selected from ethylenediaminetetracetic acid (EDTA), glutathione reduced (GL) and salts thereof. For instance, the one or more multidentate ligands may comprise ethylenediaminetetracetic acid (EDTA) or glutathione reduced (GL). The structures of these two compounds are shown below.

The process of the invention may comprise treating the metal halide perovskite with a single multidentate ligand which is an organic compound or salt thereof as defined herein. Often, the process of the invention comprises treating the metal halide perovskite with two or more multidentate ligands which are organic compounds or salts thereof as defined herein. For instance, the one or more multidentate ligands may comprise: (i) a first organic compound or a salt thereof, which first organic compound comprises two or more carboxylic acid groups; and (ii) a second organic compound or a salt thereof, which second organic compound comprises one or more carboxylic acid groups, one or more thiol groups and optionally one or more amino groups. The one or more multidentate ligands may comprise: (i) a first organic compound or a salt thereof, which first organic compound comprises two or more carboxylic acid groups and one or more amine groups; and (ii) a second organic compound or a salt thereof, which second organic compound comprises two or more carboxylic acid groups, one or more amine groups and one or more thiol groups.

Examples of the first organic compound include aminopolycarboxylic acids as define above, for instance EDTA, IDA, IDS, NTA, DTPA, EGTA, BAPTA, NOTA, DOTA, EDDS or EDDHA. Examples of the second organic compound include glutathione reduced (GL), glutathione oxidised, penicillamine (Pen), cysteine (Cys), alanyl-cysteine (AlaCys), cysteinyl-glycine (CysGly) and dimercaptosuccinic acid (DMSA). If two multidentate ligands are used, the molar ratio of the first and second organic compounds is typically from 5:1 to 1:5, for instance from 2:1 to 1:2.

The one or multidentate ligands may comprise (i) ethylenediaminetetracetic acid (EDTA) or a salt thereof and (ii) glutathione reduced (GL) or a salt thereof. Preferably, the one or more multidentate ligands comprise ethylenediaminetetracetic acid (EDTA) and glutathione reduced (GL).

One or more passivating agents may also be used to treat the metal halide perovskite. A passivating agent is a compound which passivates under-coordinated ions at the surface of the metal halide perovskite. Passivating agents typically bind to the under-coordinated ions and remain bound to the surface of the metal halide perovskite. Accordingly, in the process of the invention (a) the composition comprising a metal halide perovskite may further comprise a passivating agent or (b) the process may further comprise treating the metal halide perovskite with a passivating agent. In option (a), the composition comprising the metal halide perovskite already comprises the passivating agent, for instance if the passivating agent was introduced when the composition comprising the metal halide perovskite was produced. For instance, the process may comprise treating a composition comprising the metal halide perovskite and one or more passivating agents with the one or more multidentate ligands. The one or more passivating agents may be chemically bound to the metal halide perovskite. In option (b), the process further comprises treating the composition comprising the metal halide perovskite with a passivating agent. The composition may be treated with the passivating agent before, after or at the same time as treating the composition with the one or more multidentate ligands. Treating the composition comprising the metal halide perovskite with a passivating agent typically comprises contacting the composition and the passivating agent in the presence of a solvent.

The passivating agent may be any suitable passivating agent. Typically the passivating agent is an organic compound comprising a heteroatom with a lone pair which is able to bond (for instance by a chemical bond) to an under-coordinated ion at the surface of the metal halide perovskite. The passivating agent may be an amine compound, a sulfur-containing compound, a phosphine compound or a halogen bond donor compound. The amine compound may be a primary amine, a secondary amine or a tertiary amine, for instance pyridine or a derivative thereof. The sulfur-containing compound may be thiophene or a derivative thereof. The halogen bond donor compound may be iodopentafluorobenzene.

Preferably, when present, the passivating agent is a compound comprising an amine group or a carboxylic acid group, or a salt thereof. The compound comprising an amine group is typically a primary amine of formula R—NH₂ where R is an organic group. For instance, the compound comprising an amine group may be an aminoalkyl trialkyloxysilane such as (3-aminopropyl)trimethoxysilane. Preferably, the passivating agent is a primary amine of formula R—NH₂ wherein R is a C₄₋₂₄ alkyl or C₄₋₂₄ alkenyl group, or a salt thereof. R may be a C₈₋₂₄ alkyl or C₈₋₂₄ alkenyl group. For instance, the passivating agent may be oleylamine ((Z)-octadec-9-enylamine). The compound comprising a carboxylic acid groups is typically a compound of formula R—COOH wherein R is a C₄₋₂₄ alkyl or C₄₋₂₄ alkenyl group, or a salt thereof. For instance, the passivating agent may be oleic acid ((Z)-octadec-9-enoic acid).

Two or more passivating agents may be used. For instance, (a) the composition comprising a metal halide perovskite may further comprise oleylamine and oleic acid or (b) the process may further comprise treating the metal halide perovskite with oleylamine and oleic acid.

The metal halide perovskite may be treated with the one or more multidentate ligands by any suitable means. Typically treating the metal halide perovskite with the one or more multidentate ligands comprises contacting a composition comprising the metal halide perovskite with the one or more multidentate ligands in the presence of a solvent. Contacting typically comprises mixing the stated components.

The metal halide perovskite (or composition comprising the metal halide perovskite) may be contacted with a composition comprising the solvent and the one or more multidentate ligands. The concentration of one or the one or more multidentate ligands in the composition may be from 0.001 to 0.5 M, for instance from 0.01 to 0.2 M. The one or more multidentate ligands (for instance in solid form) may be contacted with a composition comprising both the solvent and the metal halide perovskite. For instance, a composition comprising nanoparticles of a metal halide perovskite in a solvent may be provided, and a solid form of the one or more multidentate ligands may be added to the composition comprising the nanoparticles and the solvent. Alternatively, a composition comprising the solvent and the one or more multidentate ligands may be applied to the metal halide perovskite. After contacting the multidentate ligands and the composition comprising the metal halide perovskite, the resulting mixture may be filtered and/or centrifuged to remove undissolved multidentate ligands.

Typically, the metal halide perovskite and the one or more multidentate ligands are contacted in the presence of a solvent in which the metal halide perovskite has low solubility. For instance, the solubility of the metal halide perovskite may be no greater than 5.0 g/100 mL, no greater than 1.0 g/100 mL, no greater than 0.1 g/100 mL, no greater than 0.01 g/100 ml, or no greater than 0.001 g/100 ml. Preferably, the solubility of the metal halide perovskite in the solvent is no greater than 0.1 g/100 mL. The solvent may comprise an aprotic solvent or an alcohol. Examples of alcohols include methanol, ethanol and isopropanol. Typically the solvent comprises an aprotic solvent. For instance, the solvent may comprise an ether, an ester, or an aromatic solvent. The ether may be a dialkyl ether (for instance dimethyl ether, diethyl ether, methyl ethyl ether or methyl tert-butyl ether), anisole (methyl phenyl ether), tetrahydrofuran, tetrahydropyran or 1,4-dioxane. The ester may be an alkyl alkanoate ester, for instance methyl acetate or ethyl acetate. The aromatic solvent may be benzene, chlorobenzene, dichlorobenzene, toluene, xylene or cumene. The solvent may comprise at least 90 wt % of the stated compounds, or at least 99 wt % of the stated compounds.

Typically, the solvent is an aprotic solvent or a non-polar aprotic solvent. The solvent may be a polar aprotic solvent. Preferably, the solvent comprises benzene, toluene, chlorobenzene, anisole, methyl acetate, ethyl acetate or diethyl ether. For instance, the process of the invention may comprise preparing a solution of the one or more multidentate ligands in a solvent which is an aromatic solvent and treating the metal halide perovskite with the solution of the one or more multidentate ligands.

The metal halide perovskite and the one or more multidentate ligands may be contacted for any amount of time suitable for chemical etching of the metal halide perovskite surface to take place. For instance, the composition comprising the metal halide perovskite may be contacted with a composition comprising the one or more multidentate ligands for from about 0.1 to about 2000 seconds, or from about 1 to about 60 second, or from about 1 to about 10 seconds. The composition comprising the metal halide perovskite may be treated with the one or more multidentate ligands for longer periods, for instance from 6 to 24 hours, or from 8 to 16 hours. The treatment may be stopped at the end of the amount of time by removing the metal halide perovskite from the composition comprising the one or more multidentate ligands, or by quenching the treatment, for instance by adding a rinsing solvent as defined below.

Treating the composition comprising the metal halide perovskite with the one or more multidentate ligands is typically conducted at a temperature from 15° C. to 70° C. or from 20° C. to 30° C.

The process typically further comprises rinsing the metal halide perovskite with a rinsing solvent after treatment with the one or more multidentate ligands. The rinsing solvent can remove the one or more multidentate ligands including the metal ions which are complexed by the one or more multidentate ligands. The rinsing solvent may be as defined above for the solvent in which the metal halide perovskite and multidentate ligands are contacted.

Typically, the rinsing solvent is an aprotic solvent or a non-polar aprotic solvent. For instance, the rinsing solvent may comprise benzene, toluene, chlorobenzene, anisole, methyl acetate, ethyl acetate or diethyl ether. Rinsing the composition with the rinsing solvent typically comprises dipping the composition in the rinsing solvent or washing the composition with the rinsing solvent.

The metal halide perovskite typically comprises a metal halide perovskite of formula (I):

[A][M][X]₃ (I)

wherein: [A] comprises one or more first cations; [M] comprises one or more metal dications; and [X] comprises one or more halide anions. If [A] is one first cation (A), [M] is two metal dications (M¹ and M²), and [X] is one halide anion (X), the metal halide perovskite may comprise a compound of formula A(M¹,M²)X₃, i.e. a compound of formula AM¹_{y}M²_{(1-y)}X₃ wherein y is between 0.0 and 1.0, for instance from 0.05 to 0.95. Such materials may be referred to as mixed ion materials.

The one or more halide anions typically comprise one or more halide anions selected from I, Br⁻ and Cl⁻. [A] may comprise a single first cation and [M] may comprise a single metal dication. The crystalline compound may accordingly be a compound of formula AM[X]₃ which may, for instance, be a mixed halide perovskite.

Typically, the metal halide perovskite comprises lead or tin. Preferably the metal halide perovskite comprises lead. Typically, the metal halide perovskite comprises iodide and bromine.

The metal halide perovskite may be an organic-inorganic perovskite wherein the one or more first cations (A) comprise an organic cation. The perovskite may alternatively be an all inorganic perovskite in which the one or more first cations are metal cations (for instance selected from K⁺, Rb⁺ and Cs⁺). The one or more first cations (A) are typically selected from K⁺, Rb⁺, Cs⁺, (NR¹R²R³R⁴)⁺, (R¹R²N═CR³R⁴)⁺, (R¹R²N—C(R⁵)═NR³R⁴)⁺ and (R¹R²N—C(NR⁵R⁶)═NR³R⁴)⁺, wherein each of R¹, R², R³, R⁴, R⁵ and R⁶ is independently H, unsubstituted or substituted C₁₋₂₀ alkyl or unsubstituted or substituted aryl. Each R¹, R², R³, R⁴, R⁵ and R⁶ is preferably selected from H and C₁₋₁₀ alkyl optionally substituted with phenyl. Each R¹, R², R³, R⁴, R⁵ and R⁶ may be H or methyl.

Preferably, the one or more first cations are selected from Cs⁺, (CH₃NH₃)⁺ and (H₂N—C(H)═NH₂)⁺. The one or more first cations preferably comprise Cs⁺ and (H₂N—C(H)═NH₂)⁺. The one or more first cations may alternatively be Cs⁺ as sole first cation or (CH₃NH₃)⁺ as sole first cation.

The one or more metal cations (M) are typically selected from Pb²⁺, Ca²⁺, Sr²⁺, Cd²⁺, Cu²⁺, Ni²⁺, Mn²⁺, Fe²⁺, Co²⁺, Pd²⁺, Ge²⁺, Sn²⁺, Yb²⁺, Eu²⁺, Bi³⁺, Sb³⁺, Pd⁴⁺, W⁴⁺, Re⁴⁺, Os⁴⁺, Ir⁴⁺, Pt⁴⁺, Sn⁴⁺, Pb⁴⁺, Ge⁴⁺ and Te⁴⁺.

The metal halide perovskite may be a compound of formula [A]Pb_{z}Sn_{(1-z)}[X]₃, where z is from 0.0 to 1.0. When z is 0.0, the formula comprises only Sn²⁺ as the one or more metal cations. When z is 1.0, the formula comprises only Pb²⁺ as the one or more metal cations. z may for instance be from 0.1 to 0.9, in which case the compound is a mixed metal perovskite. In this formula, [A] typically comprises one or more of Cs⁺, (CH₃NH₃)⁺ and (H₂N—C(H)═NH₂)⁺ and [X] typically comprises one or more of I, Br and Cl⁻.

The perovskite may be compound of formula CH₃NH₃PbI₃, CH₃NH₃PbBr₃, CH₃NH₃PbCl₃, CH₃NH₃PbF₃, CH₃NH₃PbBr_{3y}I_{3(1-y)}, CH₃NH₃PbBr_{3y}Cl_{3(1-y)}, CH₃NH₃PbI_{3y}Cl_{3(1-y)}, CH₃NH₃PbI_{3(1-y)}Cl_{3y}, CH₃NH₃SnI₃, CH₃NH₃SnBr₃, CH₃NH₃SnCl₃, CH₃NH₃SnF₃, CH₃NH₃SnBrI₂, CH₃NH₃SnBr_{3y}I_{3(1-y)}, CH₃NH₃SnBr_{3y}Cl_{3(1-y)}, CH₃NH₃SnF_{3(1-y)}Br_{3y}, CH₃NH₃SnI_{3y}Br_{3(1-y)}, CH₃NH₃SnI_{3y}Cl_{3(1-y)}, CH₃NH₃SnF_{3(1-y)}I_{3y}, CH₃NH₃SnCl_{3y}Br_{3(1-y)}, CH₃NH₃SnI_{3(1-y)}Cl_{3y} and CH₃NH₃SnF_{3(1-y)}Cl_{3y}, CH₃NH₃CuI₃, CH₃NH₃CuBr₃, CH₃NH₃CuCl₃, CH₃NH₃CuF₃, CH₃NH₃CuBrI₂, CH₃NH₃CuBr_{3y}I_{3(1-y)}, CH₃NH₃CuBr_{3y}Cl_{3(1-y)}, CH₃NH₃CuF_{3(1-y)}Br_{3y}, CH₃NH₃CuI_{3y}Br_{3(1-y)}, CH₃NH₃CuI_{3y}Cl_{3(1-y)}, CH₃NH₃CuF_{3(1-y)}I_{3y}, CH₃NH₃CuCl_{3y}Br_{3(1-y)}, CH₃NH₃CuI_{3(1-y)}Cl_{3y}, or CH₃NH₃CuF_{3(1-y)}Cl_{3y} where y is from 0 to 1; a perovskite compound of formula (H₂N—C(H)═NH₂)PbI₃, (H₂N—C(H)═NH₂)PbBr₃, (H₂N—C(H)═NH₂)PbCl₃, (H₂N—C(H)═NH₂)PbF₃, (H₂N—C(H)═NH₂)PbBr_{3y}I_{3(1-y)}, (H₂N—C(H)═NH₂)PbBr_{3y}Cl_{3(1-y)}, (H₂N—C(H)═NH₂)PbI_{3y}Br_{3(1-y)}, (H₂N—C(H)═NH₂)PbI_{3y}C_{3(1-y)}, (H₂N—C(H)═NH₂)PbCl_{3y}Br_{3(1-y)}, (H₂N—C(H)═NH₂)PbI_{3(1-y)}Cl_{3y}, (H₂N—C(H)═NH₂)SnI₃, (H₂N—C(H)═NH₂)SnBr₃, (H₂N—C(H)═NH₂)SnCl₃, (H₂N—C(H)═NH₂)SnF₃, (H₂N—C(H)═NH₂)SnBrI₂, (H₂N—C(H)═NH₂)SnBr_{3y}I_{3(1-y)}, (H₂N—C(H)═NH₂)SnBr_{3y}Cl_{3(1-y)}, (H₂N—C(H)═NH₂)SnF_{3(1-y)}Br_{3y}, (H₂N—C(H)═NH₂)SnI_{3y}Br_{3(1-y)}, (H₂N—C(H)═NH₂)SnI_{3y}Cl_{3(1-y)}, (H₂N—C(H)═NH₂)SnF_{3(1-y)}I_{3y}, (H₂N—C(H)═NH₂)SnCl_{3y}Br_{3(1-y)}, (H₂N—C(H)═NH₂)SnI_{3(1-y)}Cl_{3y}, (H₂N—C(H)═NH₂)SnF_{3(1-y)}Cl_{3y}, (H₂N—C(H)═NH₂)CuI₃, (H₂N—C(H)═NH₂)CuBr₃, (H₂N—C(H)═NH₂)CuCl₃, (H₂N—C(H)═NH₂)CuF₃, (H₂N—C(H)═NH₂)CuBrI₂, (H₂N—C(H)═NH₂)CuBr_{3y}I_{3(1-y)}, (H₂N—C(H)═NH₂)CuBr_{3y}Cl_{3(1-y)}, (H₂N—C(H)═NH₂)CuF_{3(1-y)}Br_{3y}, (H₂N—C(H)═NH₂)CuI_{3y}Br_{3(1-y)}, (H₂N—C(H)═NH₂)CuI_{3y}C_{3(1-y)}, (H₂N—C(H)═NH₂)CuF_{3(1-y)}I_{3y}, (H₂N—C(H)═NH₂)CuCl_{3y}Br_{3(1-y)}, (H₂N—C(H)═NH₂)CuI_{3(1-y)}Cl_{3y}, or (H₂N—C(H)═NH₂)CuF_{3(1-y)}Cl_{3y} where y is from 0 to 1; or a perovskite compound of formula (H₂N—C(H)═NH₂)ₓCs₁₋ₓPbI₃, (H₂N—C(H)═NH₂)ₓCs₁₋ₓPbBr₃, (H₂N—C(H)═NH₂)ₓCs₁₋ₓPbC₃, (H₂N—C(H)═NH₂)ₓCs₁₋ₓPbF₃, (H₂N—C(H)═NH₂)ₓCs₁₋ₓPbBr_{3y}I_{3(1-y)}, (H₂N—C(H)═NH₂)ₓCs₁₋ₓPbBr_{3y}Cl_{3(1-y)}, (H₂N—C(H)═NH₂)ₓCs₁₋ₓPbI_{3y}Br_{3(1-y)}, (H₂N—C(H)═NH₂)ₓCs₁₋ₓPbI_{3y}Cl_{3(1-y)}, (H₂N—C(H)═NH₂)ₓCs₁₋ₓPbCl_{3y}Br_{3(1-y)}, (H₂N—C(H)═NH₂)ₓCs₁₋ₓPbI_{3(1-y)}Cl_{3y}, (H₂N—C(H)═NH₂)ₓCs₁₋ₓSnI₃, (H₂N—C(H)═NH₂)ₓCs₁₋ₓSnBr₃, (H₂N—C(H)═NH₂)ₓCs₁₋ₓSnCl₃, (H₂N—C(H)═NH₂)ₓCs₁₋ₓSnF₃, (H₂N—C(H)═NH₂)ₓCs₁₋ₓSnBrI₂, (H₂N—C(H)═NH₂)ₓCs₁₋ₓSnBr_{3y}I_{3(1-y)}, (H₂N—C(H)═NH₂)ₓCs₁₋ₓSnBr_{3y}Cl_{3(1-y)}, (H₂N—C(H)═NH₂)ₓCs₁₋ₓSnF_{3(1-y)}Br_{3y}, (H₂N—C(H)═NH₂)ₓCs₁₋ₓSnI_{3y}Br_{3(1-y)}, (H₂N—C(H)═NH₂)ₓCs₁₋ₓSnI_{3y}C_{3(1-y)}, (H₂N—C(H)═NH₂)ₓCs₁₋ₓSnF_{3(1-y)}I_{3y}, (H₂N—C(H)═NH₂)ₓCs₁₋ₓSnCl_{3y}Br_{3(1-y)}, (H₂N—C(H)═NH₂)ₓCs₁₋ₓSnI_{3(1-y)}Cl_{3y}, (H₂N—C(H)═NH₂)ₓCs₁₋ₓSnF_{3(1-y)}Cl_{3y}, (H₂N—C(H)═NH₂)ₓCs₁₋ₓCuI₃, (H₂N—C(H)═NH₂)ₓCs₁₋ₓCuBr₃, (H₂N—C(H)═NH₂)ₓCs₁₋ₓCuCl₃, (H₂N—C(H)═NH₂)ₓCs₁₋ₓCuF₃, (H₂N—C(H)═NH₂)ₓCs₁₋ₓCuBrI₂, (H₂N—C(H)═NH₂)ₓCs₁₋ₓCuBr_{3y}I_{3(1-y)}, (H₂N—C(H)═NH₂)ₓCs₁₋ₓCuBr_{3y}Cl_{3(1-y)}, (H₂N—C(H)═NH₂)ₓCs₁₋ₓCuF_{3(1-y)}Br_{3y}, (H₂N—C(H)═NH₂)ₓCs₁₋ₓCuI_{3y}Br_{3(1-y)}, (H₂N—C(H)═NH₂)ₓCs₁₋ₓCuI_{3y}Cl_{3(1-y)}, (H₂N—C(H)═NH₂)ₓCs₁₋ₓCuF_{3(1-y)}I_{3y}, (H₂N—C(H)═NH₂)ₓCs₁₋ₓCuCl_{3y}Br_{3(1-y)}, (H₂N—C(H)═NH₂)ₓCs₁₋ₓCuI_{3(1-y)}Cl_{3y}, or (H₂N—C(H)═NH₂)ₓCs₁₋ₓCuF_{3(1-y)}Cl_{3y} where x is from 0 to 1 and y is from 0 to 1. x may for instance be from 0.05 to 0.95. y may for instance be from 0.05 to 0.95. Preferably, the metal halide perovskite is CH₃NH₃PbBr_{3y}I_{3(1-y)}, CsPbBr_{3y}I_{3(1-y)} or Csₓ(H₂N—C(H)═NH₂)₍₁₋ₓ₎PbBr_{3y}I_{3(1-y)}, where x is from 0.0 to 1.0 and y is from 0.0 to 1.0. For instance, the metal halide perovskite may be CH₃NH₃PbI₃, CsPbBr_{3y}I_{3(1-y)} or Csₓ(H₂N—C(H)═NH₂)₍₁₋ₓ₎PbBr_{3y}I_{3(1-y)}, where x is from 0.05 to 0.95 and y is from 0.05 to 0.95.

Preferably, the metal halide perovskite is a compound of formula Csₓ(H₂N—C(H)═NH₂)₍₁₋ₓ₎PbBr_{3y}I_{3(1-y)}, where x is from 0.0 to 1.0 and y is from 0.0 to 1.0. Typically, x is from 0.05 to 0.50 or from 0.10 to 0.30. x may for instance be from 0.15 to 0.20. Typically, y is from 0.01 to 0.70 or from 0.20 to 0.60. y may for instance be from 0.30 to 0.50. The metal halide perovskite is preferably Cs_{0.2}(H₂N—C(H)═NH₂)_{0.8}Pb(Br_{0.4}I_{0.6})₃ or Cs_{0.17}(H₂N—C(H)═NH₂)_{0.83}Pb(Br_{0.4}I_{0.6})₃.

The composition comprising the metal halide perovskite preferably comprises a metal halide perovskite which is (CH₃NH₃)Pb(Br_{y}I_{(1-y)})₃ or Csₓ(H₂N—C(H)═NH₂)₍₁₋ₓ₎Pb(Br_{y}I_{(1-y)}))₃, where x is from 0.0 to 1.0 and y is from 0.0 to 1.0, preferably wherein y is from 0.01 to 0.99.

The composition comprising the metal halide perovskite may comprise the metal halide perovskite in a number of different forms. Typically, the composition comprising a metal halide perovskite comprises: (i) particles comprising the metal halide perovskite; (ii) a polycrystalline form of the metal halide perovskite; or (iii) a single crystal of the metal halide perovskite.

Preferably, the metal halide perovskite is in the form of particles comprising the metal halide perovskite. For instance, the process may comprise treating a composition comprising particles comprising the metal halide perovskite with the one or more multidentate ligands. More preferably, the metal halide perovskite is in the form of nanoparticles comprising the metal halide perovskite. The nanoparticles are typically particles having an average particle size of from 1.0 nm to 500 nm or an average particle size of from 1 nm to 100 nm. The average particle size is typically the Dv50 particle size, for instance as measured by laser diffraction. The nanoparticles comprising the metal halide perovskite may have an average cubic dimension of less than 30 nm, or less than 15 nm.

The composition comprising nanoparticles of the metal halide perovskite may be prepared by a method comprising (i) preparing a solution of a metal halide and an alkyl ammonium halide and (ii) injecting the solution into an arene solvent comprising a passivating agent. For instance, a solution of lead (II) iodide and methylammonium bromide in an acetonitrile/methylamine solvent may be injected into toluene comprising olelyamine and oleic acid.

If the composition comprises a polycrystalline form of the metal halide perovskite or a single crystal of the metal halide perovskite, the metal halide perovskite is typically in the form of a layer. For instance, the composition comprising the metal halide perovskite may be produced by disposing a solution of the metal halide perovskite on a substrate and drying the solution to produce a layer of the metal halide perovskite.

The composition comprising the metal halide perovskite may comprise a substrate and, disposed on the substrate, a layer of the metal halide perovskite. The substrate typically comprises a layer of an electrode material. The substrate may comprise a layer of an electrode material and a layer of a hole injection layer. The electrode material is typically a transparent conducting oxide such as indium tin oxide (ITO).

The process produces a modified metal halide perovskite. The modified metal halide perovskite is a chemically etched metal halide perovskite. Typically, the modified metal halide perovskite has an increased luminescence efficiency relative to the metal halide perovskite prior to treatment. For instance the photoluminescence quantum yield (PLQY) of the modified metal halide perovskite may be at least 10% greater or at least 20% greater than the PLQY of the metal halide perovskite prior to treatment.

The modified metal halide perovskite typically also has a reduced thickness or a reduced particle or crystal size relative to the metal halide perovskite prior to treatment. For instance, the volume of the modified metal halide perovskite present in the composition may be at least 5% or at least 10% less than the volume of the metal halide perovskite present in the composition prior to treatment.

The invention also provides use of one or more multidentate ligands as defined herein for chemically etching the surface of the metal halide perovskite, for instance for selectively chemically etching metal ions from the surface of the metal halide perovskite. The use may be for increasing the luminescence efficiency of the metal halide perovskite by chemically etching the surface of the metal halide perovskite.

The invention also provides a chemically etched metal halide perovskite obtainable by the process for chemically etching the surface of a metal halide perovskite. The metal halide perovskite may comprise lead and the chemically etched metal halide perovskite may have a lead-poor surface. For instance, the composition of the surface region of the chemically etched metal halide perovskite may be AM_{(1-q)}X₃ where A, M and X are as defined herein and q may be from 0.00001 to 0.2 or from 0.001 to 0.1. The surface region of the chemically etched metal halide perovskite may be the part of the metal halide perovskite extending up to 1.0 nm, or up to 2.0 nm, from the surface of the metal halide perovskite. The invention also provides a semiconductor device comprising the chemically etched metal halide perovskite.

The process for producing a semiconductor device according to the invention comprises the process for chemically etching the surface of a metal halide perovskite. The process typically further comprises disposing on the chemically etched metal halide perovskite (which may be in the form of a layer) a layer of a p-type semiconductor or a layer of a n-type semiconductor. Often, the process typically comprises disposing on the chemically etched metal halide perovskite a layer of a p-type semiconductor. The n-type or p-type semiconductor may be an organic p-type semiconductor. Suitable p-type semiconductors may be selected from polymeric or molecular hole transporters. The layer of a p-type semiconductor or a layer of a n-type semiconductor is typically disposed on the metal halide perovskite by solution-processing, for instance by disposing a composition comprising a solvent and the n-type or p-type semiconductor. The solvent may be selected from polar solvents, for instance chlorobenzene or acetonitrile. The thickness of the layer of the p-type semiconductor or the layer of the n-type semiconductor is typically from 50 nm to 500 nm.

The process typically further comprises disposing on the layer of the p-type semiconductor or n-type semiconductor a layer of a second electrode material. The second electrode material may be as defined above for the first electrode material. Typically, the second electrode material comprises, or consists essentially of, a metal. Examples of metals which the second electrode material may comprise, or consist essentially of, include silver, gold, copper, aluminium, platinum, palladium, or tungsten. The second electrode may be disposed by vacuum evaporation. The thickness of the layer of a second electrode material is typically from 5 nm to 100 nm.

The semiconductor device is typically an optoelectronic device, for instance a light emitting device or a photovoltaic device. Preferably, the optoelectronic device is a light emitting device. The light emitting device may have a photoluminescence peak of from 615 nm to 640 nm.

The invention also provides a composition comprising a metal halide perovskite and one or more multidentate ligands, wherein the one or more multidentate ligands comprise an organic compound or a salt thereof, which organic compound comprises three or more binding groups, which three or more binding groups comprise two or more carboxylic acid groups. The composition typically further comprises a solvent as defined herein. For instance, the solvent may be an ether, an ester, or an aromatic solvent. The ether may be a dialkyl ether (for instance dimethyl ether, diethyl ether, methyl ethyl ether or methyl tert-butyl ether), anisole (methyl phenyl ether), tetrahydrofuran, tetrahydropyran or 1,4-dioxane. The ester may be an alkyl alkanoate ester, for instance methyl acetate or ethyl acetate. The aromatic solvent may be benzene, chlorobenzene, dichlorobenzene, toluene, xylene or cumene. The composition may comprise a metal halide perovskite, one or more multidentate ligands and a solvent which is an ester or an aromatic solvent. Typically, the composition comprises nanoparticles comprising the metal halide perovskite.

The one or more multidentate ligands may be as defined herein. For instance, the organic compound may comprise one or more thiol groups. The composition may comprise glutathione reduced and/or EDTA.

Although the majority of the one or more multidentate ligands are removed during the process of the invention for chemically etching a metal halide perovskite, some of the multidentate ligands may remain, for instance bound to the surface of the metal halide perovskite. The invention accordingly provides a semiconductor device comprising a composition according to the invention. The semiconductor device may comprise a metal halide perovskite and one or more multidentate ligands, wherein the one or more multidentate ligands comprise an organic compound or a salt thereof, which organic compound comprises three or more binding groups, which three or more binding groups comprise two or more carboxylic acid groups. For instance, the semiconductor device may comprise a metal halide perovskite and an aminopolycarboxylic acid (for instance EDTA) or a peptide comprising a thiol group (for instance GL).

The semiconductor device is typically an optoelectronic device, for instance a light emitting device. Preferably, the light emitting device has a photoluminescence peak of from 615 nm to 640 nm.

The invention is described in more detail in the following examples.

### EXAMPLES

### Example 1—Treatment of Perovskite Nanocrystals

Methods

All nanocrystal (NC) syntheses were carried out at ambient conditions in a fume hood.

Materials All chemicals were used as received without further purification. Lead iodide (PbI₂) (99.99%) was purchased from TCI Chemicals; methylammonium iodide (MAI) and methylammonium bromide (MABr) from Dyesol; oleic acid (99.0%), oleylamine (70%), methylamine (MA) solution (33% in absolute ethanol), ethylenediaminetetraacetic acid (EDTA, anhydrous, ≥99%), and L-glutathione reduced (GL, ≥98.0%) from Sigma-Aldrich. All solvents such as toluene, acetonitrile, and methyl acetate were anhydrous and were purchased from Sigma-Aldrich. PEDOT.PSS (AI 4083), Poly-TPD, and TPBi were purchased from OSM. TFB was purchased from Ossila.

Preparation of Lead Mixed Halide Perovskite Precursor

A perovskite precursor solution was prepared according to Hassan, Y. et al (Journal of the American Chemical Society 141, 1269-1279), where 922 mg of PbI₂ and 223 mg of MABr were mixed with 4 mL of acetonitrile (ACN) and shaken to form a green-black suspension. Dry CH₃NH₃ (MA) gas was bubbled through the suspension to form a compound solvent, hereafter referred to as ACN/MA.

Synthesis of MAPb(I₁₋ₓBrₓ)₃ Perovskite NCs for Red Emission

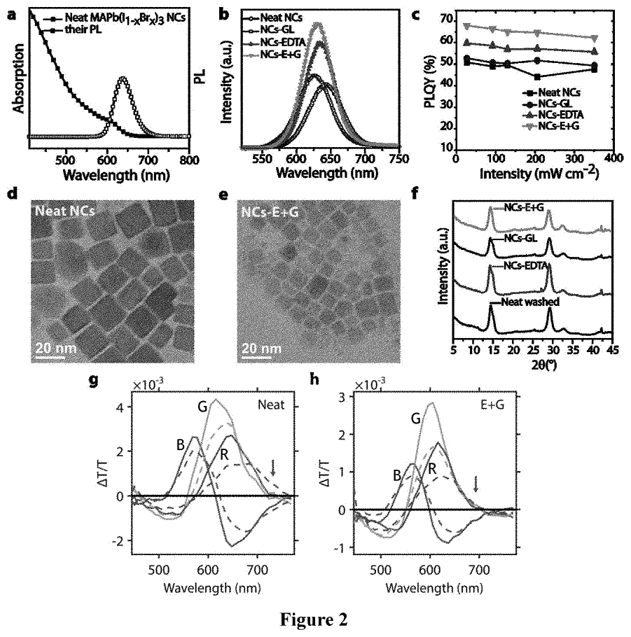

The synthesis of the MAPb(I₁₋ₓBrₓ)₃ NCs was carried out by injecting 0.2 mL of perovskite precursor dissolved in ACN/MA into −60° C. toluene containing 2 mL of oleic acid (OA) and 0.2 mL oleylamine (OLA). The NCs immediately nucleated, turning the suspension red. The reaction was continued for 1-2 min to allow for crystal growth before the NC suspension was immersed into an ice bath. We synthesised six batches of NCs simultaneously, collected them into three centrifuge tubes (each containing 10 mL of NCs), and the NCs were iteratively precipitated by adding 20 mL of anhydrous methyl acetate. The NCs were separated from excess unreacted ligands/precursors and purified by centrifugation at 8,000 rpm for 10 min, then re-dispersed into 5 mL toluene. We added 10 mL methyl acetate to each tube and repeated the purification process before the NCs were re-dissolved in toluene to a concentration of 40 mg mL−1 for further characterisation. These purified NCs, capped with OA and OLA, are denoted as “neat NCs.” These neat NCs exhibit PL at 630 nm, and their tetragonal phase was confirmed by powder X-ray diffraction (PXRD), FIG. 2f.

Ligand Treatment of MAPb(I₁₋ₓBrₓ)₃ Perovskite NCs

The NCs underwent two washing cycles with a methyl acetate mixture, as described above. Each NC batch was dispersed in 2 mL of toluene after the washing process. Six batches of washed NCs were combined to make a 12 mL (40 mg mL⁻¹) stock solution. This solution was centrifuged another time at 5,000 rpm for 5 minutes to remove aggregates and large particles. The collected supernatant was divided into two portions: one was used as the control neat sample, while the other was treated by a new ligand. The ligand was an equimolar mixture of EDTA and GL (denoted E+G). Typically, 2 mmol of ligand was added to 3 mL of NCs in toluene and stirred overnight (˜12 hrs) at room temperature. The unreacted ligand powder was separated from the NCs after ligand treatment by centrifugation at 8,000 rpm for 10 min. The collected supernatant was filtered using a PTFE syringe filter (Whatman, 0.2 μm) and stored for further characterisation and device work.

Transient Absorption Spectroscopy (TAS) of MAPb(I₁₋ₓBrₓ)₃ NCs

A Ti:Sapphire laser (Coherent Astrella) operating at 1 kHz pumped an optical parametric amplifier (Light Conversion, Topas Prime Plus) to generate 520 nm pump pulses. The 800 nm fundamental was used to generate white light probe pulses in a sapphire plate. The TAS pump pulse energy was 106 μJ cm⁻². The broadband probe pulse energies were 124 μJ cm⁻² and 146 μJ cm⁻² for the E+G and C films, respectively. Transient absorption spectroscopy (TAS) spectra were collected using a homebuilt instrument with 100 fs time resolution and pump-probe time delays of up to 800 ps. The TAS signal at alternate time delays was collected in ascending order, and the signal at the remaining time delays in descending order, to ensure that any changes in the sample during the scan were not systematically encoded into the transient. Each scan required 50 s. 72 TAS spectra for each film were measured prior to s of exposure to a 405 nm CW laser with the power density set at 7.09 W cm⁻². The 405 nm laser also acted as the excitation source for the measurement of fluorescence spectra. Fluorescence was collected through a fibre optic cable (Thorlabs M53L01) by a portable spectrometer (Ocean Optics, Flame-T). After completing the exposure, the TAS instrument was initialised, a process that requires 40 s. TAS scans were then collected, with a few seconds of exposure to the 405 nm CW laser before and after each scan to compensate for the recovery of the halide migration during the TAS scan. This procedure was repeated for 60 TAS scans.

Absorbance, fluorescence, and TAS measurements were performed on OA/OLA- and EG-capped NCs in spin-cast encapsulated films. The average wavelength of the fluorescence immediately before and after each TAS scan was used to estimate the average fluorescence wavelength during the scan. This estimates the average amount of halide segregation over 60 TAS scans. The duration of exposure to the 405 nm light after each scan was set to minimise the change in the average fluorescence wavelength during the 60 TAS scans. TAS measurements were performed on different spots on each film using different durations of 405 nm exposure between TAS scans until a small standard deviation in the average fluorescence wavelength was achieved. This indicated that, with this additional irradiation, the NCs were not continuing to undergo further halide segregation nor recovery of segregation during the 60 TAS scans.

### Calculation of the EQE-EL Limit

The observed EQE-EL of more than 20% appears to be at the limit of what is feasible when considering optical outcoupling efficiencies from perovskite thin films in LED device structures. However, the precise outcoupling efficiency depends strongly upon the refractive index of the emission layer, and furthermore, photon recycling can contribute to enabling waveguided light to be reabsorbed and externally emitted from the device. In order to quantify this is in more detail, we firstly estimated the refractive index of our nanocrystal films using spectroscopic ellipsometry and estimate an n=˜1.82 @ 620 nm. Considering a thin film on glass, with an n=1.82, and accounting for emission from both the perovskite/air and perovskite/glass interfaces, we determine an outcoupling efficiency of 32.4%. The observations of a PLQY of 70% for such films is clearly in excess of this, but can be understood by accounting for photon recycling. For our films, with an outcoupling efficiency of 32.4% and an external PLQY of 70%, an internal PLQY of 87.6% was estimated (further details of this calculation are provided below). For the LEDs, this calculation is slightly more complicated since there are a larger number of material layers, there is a reflective rear electrode, and parasitic absorption can occur in the charge injection layers and electrode materials. However, detailed calculations have been made for organic light-emitting diodes with very similar device stacks and refractive indices for the materials used, including the emission layer at n˜1.8. Putting out internal PLQY of 87.8% into the calculated escape cone efficiencies results in an estimated EQE for EL of 32.4%. Therefore, the measured EQE-EL of 20% is entirely feasible, and there yet remains a capacity for further improvement.

Details of the Internal PLQY Calculation

Here we measure the PLQY of a perovskite film coated upon a glass slide measured in an integrated sphere. The light will be isotopically emitted within the perovskite film, and a certain fraction emitted within a specific solid-angle will escape from the front and back surface of the film, with a considerable fraction of the light totally internally reflected and reabsorbed in the plane of the film. Since the overlap of emission and absorption spectra are significant for these perovskite materials, it is estimated that within a few tens of microns, more than 90% of the waveguided light will be reabsorbed and hence very little light will be emitted from the edges of perovskite film coated on the 2×2 cm glass slides. The analysis which is set out below, which includes realistic parameters, determines the relationship between measured PLQE and internal PLQE. The probability for a photon isotopically emitted from within one medium, to be transmitted through an interface between the medium within which it was emitted and the adjacent medium, with refractive indices n₁ and n₂ respectively, can be estimated as

$${n}_{trans} = \frac{{Ω}_{esc}}{4 π} T \approx \frac{{n}_{2}^{3}}{{{n}_{1} ( {n}_{1} + {n}_{2} )}^{2}}$$

where Ω_{esc} is the escape solid angle, and T is the transmittance. An ellipsometry measurement estimates the refractive index of perovskite NC films to be ˜1.82 @ 620 nm. Taking the refractive index of air, glass, and the perovskite NC film to be 1, 1.5, and 1.82 respectively, we estimate the transmission probability of a photon from the above equation for the perovskite-air interface to be 6.9% and the perovskite-glass interface to be 16.8%.

It was assumed the optical density of the NC films was 0.02 at the PL emission wavelength of 620 nm (or 2 eV). Before reaching an interface, photons will, on average, have travelled through an optical density of 0.01. Of the total photons emitted, 16.8% of the photons will be traveling towards the perovskite/glass interface within the escape cone, and 6.9% of the photons will be traveling towards the perovskite/air interface within the escape cone. The photons emitted towards the perovskite/air interface, but within the solid-angle in between the perovskite/air and perovskite/glass escape cones (which accounts for 16.8%-6.9%=9.9% of the photons), will be reflected off the perovskite/air, and then escape out of the perovskite/glass interface. Therefore, accounting for the small attenuation due to self-absorption, the total escape probability for the perovskite NC films is estimated to be

η_{esc}=10^{-0.01}·(16.8%+6.9%+10^{-0.02}·(16.8%−6.9%))=32.4%

The relation between internal PLQY (η), and measured PLQY (η_ext) is given by

$${η}_{ext} = \frac{( η \cdot {η}_{esc} )}{1 - η + ( η \cdot {η}_{esc} )}$$

Substituting the measured external PLQY of 70%, (ηₑₓₜ=0.70) and total escape probability of 32.4%, (η_{esc}=0.324), we obtain internal PLQY (η)=0.878 or 87.8%. It is noted that this expression accounts for the photon recycling and illustrates that the external measured PLQY can deviate considerably from the internal PLQY.

ICP-MS Analysis

To support the existence of this “stripped” Pb-ligand (EDTA, GL) complex in the sediment, an ICP-MS analysis of the resulting precipitates was performed (which includes the potential Pb-ligand complex and undissolved ligand) after repeated washing with toluene (10 times). As both EDTA and GL have very low solubility in toluene, this process effectively disperses and removes the remaining NCs while retaining the Pb-ligand complexes in the residue. To rule out the spurious lead content arising from remaining NCs, toluene supernatant from the final washing step was also subjected to ICP analysis. The result clearly shows an increasing quantity of precipitate lead content in the order of GL (518 μg mg⁻¹) >EG (428 μg mg⁻¹) >EDTA (354 μg mg⁻¹)-treated samples when compared to the final supernatant (nearly 0 μg mg⁻¹). To estimate whether EDTA and GL have different Pb²⁺ complexation ability, we calculated the binding energy between the two ligands and a Pb²⁺ ion. The complexes show a hemidirected coordination of the ligands, with EDTA endowed with a significantly higher binding energy to Pb²⁺ than GL, by 0.80 eV.

Fabrication of MAPb(I1−xBrx)3 NC LEDs

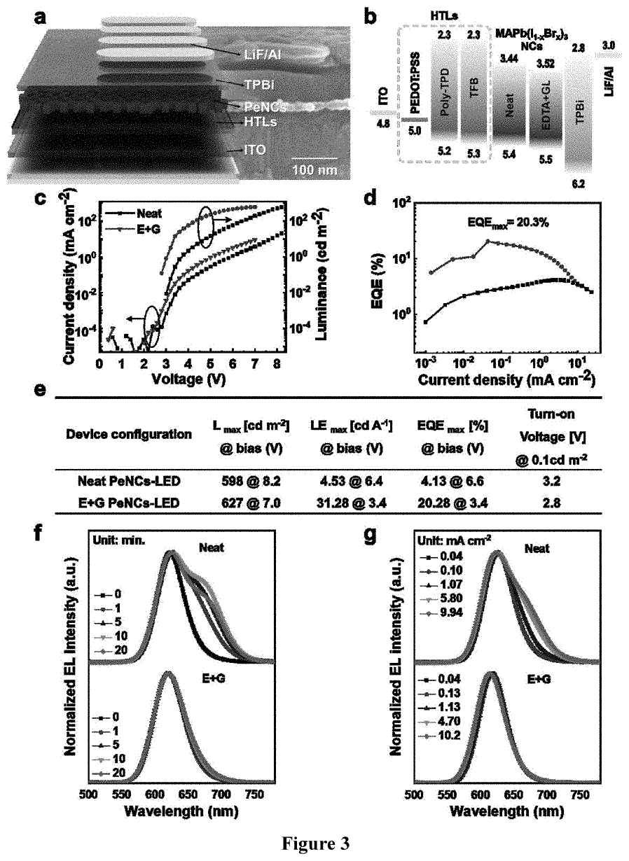

The final device stack, for which a schematic and a SEM cross-sectional image is shown in FIGS. 3a and b, includes a “triple-layer” hole-injection layer, comprising Poly(3,4-ethylenedioxythiophene):poly(p-styrene sulfonate) (PEDOT:PSS), Poly[N,N′-bis(4-butylphenyl)-N,N′-bisphenylbenzidine] (poly-TPD) and the deep work-function polymer-poly[(9,9-dioctylfluorenyl-2,7-diyl)-co-(4,4′-(N-(4-sec-butylphenyl)diphenylamine)] (TFB), followed by a thin dense layer of the perovskite NCs (˜30 nm), capped with the electron transport layer of 2,2′,2″-(1,3,5-Benzinetriyl)-tris(1-phenyl-1-H-benzimidazole) (TBPi) and a lithium fluoride/aluminium cathode. Typically, Indium tin oxide (ITO)-coated glass substrates were cleaned by an ultra-sonification process in deionised water, acetone, and isopropanol for 10 min. PEDOT:PSS was spin-coated onto an ITO substrate at 5,000 rpm for 40 s. The coated substrates were transferred to an N₂-filled glove box and annealed at 140° C. for 10 min. Poly-TPD solution (15 mg ml⁻¹) in chlorobenzene and TFB solution (20 mg mL⁻¹) in p-xylene was sequentially spin-coated onto the substrates at 4,000 rpm for 40 s. Each layer was annealed at 140° C. for 30 min. The MAPbI₂Br NCs were spin-coated onto the substrates at 2,000 rpm for 40 s. 70 nm thick layer of TPBi, 1 nm thick layer of LiF, and 80 nm thick layer of Al were sequentially deposited using a thermal evaporation system.

Solid-State ¹³C NMR

Solid-state ¹³C MAS NMR was performed at 9.4 T (KBSI Western Seoul Center) using a 4 mm Bruker triple resonance probe. The prepared nanocrystals were packed into reduced volume zirconia rotors under nitrogen atmosphere and were spun at 8 kHz. ¹³C data were acquired by ¹H-¹³C Hartmann-Hahn cross polarization sequence with 100 kHz SPINAL64 ¹H decoupling.

Solution HNMR

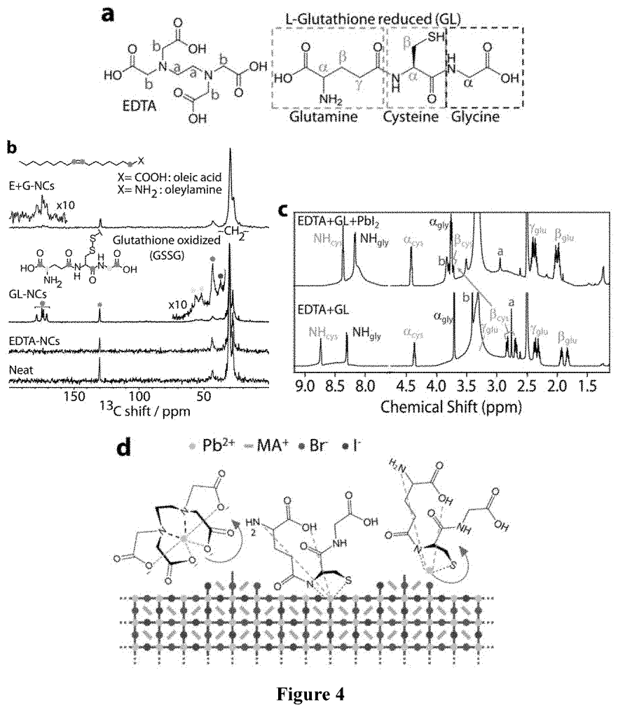

In order to assess the interaction between the ligands and Pb²⁺, ¹H NMR spectra of the ligands mixed with PbI₂ were measured. In FIG. 4b, annotated structural diagrams of the ligands are shown, indicating the different moieties responsible for the NMR resonances and the different binding units present in GL, namely, glutamine (glu), cysteine (cys) and glycine (gly). In FIG. 4c, it is observed that both ¹H signals from EDTA shift downfield and broaden, indicating multidentate complexation of EDTA to Pb²⁺. GL and PbI² were mixed in d-DMSO and two changes were observed: (i) significant broadening and increased chemical shifts of the cysteinyl βcys resonance and (ii) decreased chemical shifts of the amide NHcys resonances. The first change indicates that Pb²⁺ binds to cysteinyl sulphur. The shift of amide NHcys resonances is likely caused by the coordination of the amide NH to the S-bound Pb²⁺, as demonstrated for the case of chemically similar Cd²⁺ binding to GL. We also observe a weakening of the geminal 2J coupling of glutamine's beta protons (oglu), indicating that the COOH is also bound to Pb²⁺. The glycine's alpha proton (αgly) displayed no observable shift upon addition of PbI₂, in agreement with previous work showing that the COO⁻ group of glycine does not bind to Pb²⁺. From the ¹H NMR spectra when both ligands (E+G) are mixed with PbI₂ it is observed that all of the interaction changes present in the solutions containing the individual ligands are also present with the combined ligands, indicating that when both ligands are combined in the E+G mixture, they maintain their individual interactions with PbI₂. The proposed molecular interactions of the E+G ligands with Pb²⁺ on the NC surface are shown in FIG. 4d. It can be concluded that both EDTA and GL can coordinate with Pb²⁺ via the aforementioned binding groups in this system.

DFT Approach

The interaction of glutathione (GL) and EDTA on perovskite surfaces was modelled by the state-of-the-art DFT calculations, including dispersion interactions, to mimic the surface chemistry of perovskite NCs. Due to the uncertain nature of surfaces and their terminations in mixed halide perovskites, we focus here on MAPbI₃, which has trustful surface picture. The results are obtained considering a PbI₂-terminated surface, which is representative of the extreme situation of a fully unpassivated perovskite surface exposing undercoordinated surface Pb atoms.

The following reasoning was applied:
1) halide demixing is triggered by defect formation and/or migration.
2) most defects and migration channels are on surfaces, so surface passivation blocks defect formation, ion migration, and demixing.
3) surface passivation molecules should bind effectively to the perovskite surface and pack tightly, thus being an effective migration blocker.
4) The adsorption of single GL and EDTA molecules was considered before moving to GL-GL, EDTA-EDTA, and GL-EDTA coadsorption.

Since GL is quite a complex molecule, modelling focussed on what chemical fragment within GL is most strongly interacting with the perovskite surface.

Thus, GL and EDTA was decomposed into the possible binding moieties and calculated the fragments binding energy (BE) to the perovskite. The binding energy is defined as:

BE=E(mol@surface)−E(mol)−E(surface) (1)

The results show that the ammidic fragment of GL is the most strongly binding one.

Typically, the calculated BE of GL is very high (−1.85 eV), coming from a partial sum of all binding ingredients. EDTA interaction with the perovskite shows a lower BE than GL (−1.60 vs. −1.85 eV), with EDTA mainly binding through carboxylic groups. Although the tertiary amminic groups may show a higher BE to Pb than COOH (, steric hindrance prevents EDTA from exploiting such interaction.

To evaluate the energetics of forming a compact monolayer on the perovskite surface, thus effectively blocking all possible undercoordinated Pb atoms acting as defect-nucleating centres, next evaluated was the BE of two interacting GL, two interacting EDTA, and an interacting GL/EDTA pair on the perovskite surface. In the case of two or more interacting molecules, the BE includes both surface-molecule and molecule-molecule interactions. The E+G pair was found to have the highest binding energy, enhanced by a synergistic effect between GL and EDTA. Intermolecular hydrogen bonding between carboxylic groups of the GL and EDTA provides extra stabilisation to these surface adsorbed molecules, leading to a BE of −4.45 eV.

Most notably, while both GL and EDTA may form a compact monolayer on the perovskite surface, the strongest interaction comes from the synergistic binding of GL and EDTA, for which the highest BE to the perovskite surface is calculated. In the case of two (or more) interacting molecules, the BE includes surface/molecule and molecule/molecule interactions, delivering total BE higher than the sum of the two individual BEs. In the E+G case, the intermolecular contribution, related to intermolecular hydrogen bonding between carboxylic groups, provides an extra stabilisation to the surface adsorbed molecules, delivering the highest BE (−4.45 eV), higher than the GL/GL and EDTA/EDTA BEs.

To connect the calculated BEs to the defect-blocking properties of the respective surface-adsorbed molecules, the energetics for formation of iodine Frenkel defect pair (i.e. iodine vacancy/interstitial iodine) at the surface were considered. These defects are the energetically most probable defects at the PbI₂-terminated perovskite surface; thus, they constitute a case study to evaluate the impact of surface adsorbed molecules on defect formation energies. The formation energy of an iodine Frenkel defect pair at the PbI₂-terminated perovskite surface was calculated without passivating molecules and in the presence of GL and of E+G.

Formation of an iodine Frenkel defect on the PbI₂-terminated perovskite surface has very low formation energy (0.03 eV), in line with the instability of the unpassivated surface (complete surface passivation by MAI raises the formation energy to 0.84 eV). GL surface passivation raises the formation energy to 0.15 eV, with E+G further raising it to 0.18 eV. This clearly demonstrates the GL surface defect blocking effect and the synergistic E+G effect. To put this value into context, when modelling the PEO interaction with the same perovskite surface, a defect formation energy increase of 0.08 eV for a complete monolayer of (CH₃OCH₃, mimicking PEO) was calculated thus, the values obtained here for GL and E+G are to be considered extremely high.

To sum up, the binding of GL, EDTA, and E+G was evaluated on the perovskite surface and evaluated their ability as Frenkel defect blocking agents. The results show a synergistic effect of GL+EDTA in delivering the highest surface binding energy and the highest defect blocking activity. The key to efficient surface passivation is the concurrent action of strong molecule/surface and molecule/molecule interactions.

All simulations have been carried out with the Quantum Espresso program package. DFT calculations have been carried out on the (001) MAPbI₃ surface within the supercell approach by using the Perdew-Burke-Ernzerhof (PBE) functional by using ultrasoft pseudopotentials (shells explicitly included in calculations: I 5s, 5p; N, C 2s, 2p; O 2s 2p; H Is; Pb 6s, 6p, 5d; S 3s 3p) and a cutoff on the wavefunctions of 25 Ryd (200 Ryd on the charge density). DFT-D3 dispersion interactions were included in the calculation.

Slabs models have been built starting from the tetragonal phase of MAPbI₃ by fixing cell parameters to the experimental values and generating a 2×2 supercell in a and b directions. A 10 Å of vacuum was added along the non-periodic direction perpendicular to the slabs in all cases. A symmetric disposition of the organic cations on the external layers of the slabs has been adopted in all cases, leading to supercells with zero average dipole moments. Such an arrangement of organic cations provided a flat electrostatic potential in the vacuum region of the supercells for all the modelled slabs.

Discussion

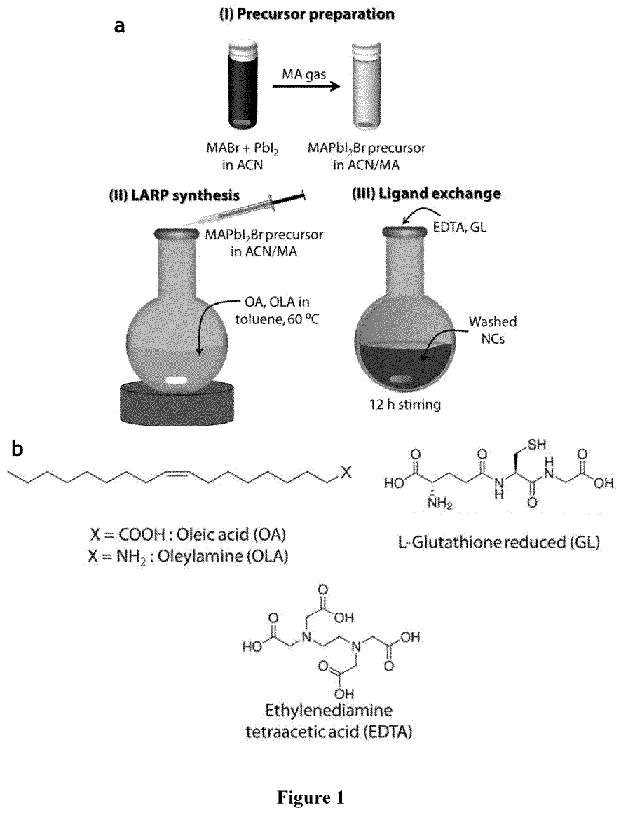

CH₃NH₃Pb(IₓBr₁₋ₓ)₃ NCs were synthesised via a modified ligand-assisted re-precipitation (LARP) method. Following purification, a ligand treatment was performed with ethylenediaminetetraacetic acid (EDTA) and L-glutathione reduced (GL) (FIG. 1). To assess the impact of the ligand treatment, time resolved photoluminescence (PL), PLQY, attenuated total reflection Fourier transform infrared spectroscopy (ATR-FTIR), X-ray photoelectron spectroscopy (XPS), and X-ray diffraction (XRD) measurements, were performed which we show in FIG. 2.

As-synthesised MAPb(IₓBr₁₋ₓ)₃ NCs in toluene exhibit PL centred at 642 nm, FIG. 2a. After ligand treatment with GL, an intensity increase and blue-shift in PL peak position to 625 nm was observed, FIG. 2b. Increased PL intensity and slight blue-shift to 635 nm was observed if EDTA is used instead. Using an equimolar mixture of EDTA and GL (denoted E+G), emission at 630 nm and increased PL intensity, PLQY and decay lifetime was observed (FIG. 2b,c), consistent with the ligand treatment decreasing the total number of active defects. These data suggest that E+G treatment is most favourable for suppressing non-radiative recombination. High-resolution transmission electron microscopy (HR-TEM) shows size reduction of the E+G NCs compared to neat NCs (average cubic dimensions of 12±1.7 nm versus 16.3±2 nm, respectively, FIG. 2d,e). Exciton energy is linearly dependent on the inverse square of NC size for weakly-confined excitons. A blue-shift in emission, consistent with quantum confinement and lattice relaxation, has been measured for perovskite nanoparticles within this size range. Furthermore, it has previously been observed that up to an 80 nm blue-shift in emission due to size confinement effects in similarly sized MAPbI₃ NCs. Hence size reduction due to ligand treatment was expected to increase quantum confinement, contributing to the observed blue-shift in emission.

Employing XPS, it was found that the I:Br ratio changes from 2:1 in the precursor solution to approximately 2:3 in synthesised NCs. A bulk emission at 647 to 655 nm was expected for this composition. Following ligand treatment, a minor enrichment in bromide content was determined, which would account for up to 8 nm blue-shift in emission for the E+G sample. A change in lattice constant of ˜0.019 Å per 10 nm shift in PL peak position for changing halide compositions in polycrystalline MAPb(I₁₋ₓBrₓ)₃ films was expected, however, XRD measurements reveal a cubic lattice constant of 6.05 Å for NC films both before and after ligand treatment (FIG. 2f). Collectively, these results suggest that both compositional changes and confinement effects are influencing the emission peak position.

To assess if the ligand treatment suppresses halide segregation and improves bandgap stability, transient absorption spectroscopy (TAS) was performed. NC films were measured with and without the E+G ligand treatment, as prepared and after exposure to a 405 nm laser. A global fit of the signal yields decay associated difference spectra (DADS), FIG. 2g,h. The sub-ps TAS decay arises from bandgap renormalisation, Auger recombination, and carrier cooling. Carriers accumulate near the band edge, causing optical bleaching at these energies. The longest TAS decay originates from carrier recombination. After irradiation for 30 s, TAS spectra for the neat sample display a new low energy bleach, visible in the longest DADS component. In contrast, the DADS line-shape for the E+G treated sample remains approximately unchanged after irradiation. The emergence of the low energy bleach in the neat sample is consistent with lower bandgap iodide-rich minority phases emerging, from which charge carriers recombine, which is suppressed in the E+G treated sample.

Segregation between NCs necessitates the creation of Br-rich and I-rich NCs. This has been observed in other perovskite NCs and results in the presence of a second, higher energy PL emission in addition to the red-shifted PL. Even at very low NC concentrations in a polymer matrix red-shifted emission was observed, with no growth of a high energy peak nor broadening of the high energy emission shoulder following irradiation. Confocal PL measurements on such films reveal a red-shifted emission under illumination from what appear to be single NCs. The lack of a high energy feature in the TAS spectra of illuminated neat NCs also indicates that Br-rich NCs are not forming, suggesting that segregation can occur within individual NCs.

Next assessed was the impact of the ligand treatment upon NC-LEDs. It was found that both EDTA and GL significantly suppress the halide segregation and improve bandgap stability, but EDTA treated NC-LEDs exhibit a small broadening in the emission-spectra during operation. On the other hand, GL treated NC-LEDs show the most stable emission-spectra but lower device efficiency. Efficient and colour-stable NC-LEDs were achieved with the E+G treatment. To better understand the role of each ligand, we ran a second ligand treatment step using a soft Lewis base of adamantane carboxylic acid (ADAC). EDTA, GL, and E+G treated NC-LEDs show a negligible peak-shift and small broadening during operation. After a subsequent ADAC treatment, EDTA and E+G treated NCs exhibit more-significant peak shift and broadening. In contrast, GL treated NC-LEDs show stable EL, even after the ADAC treatment. These observations indicate that GL is more strongly bound to the NC surface than EDTA, but EDTA appears to be important for achieving the highest efficiencies.

When choosing charge injection layers and optimising the performance of the LEDs, it was found that maximising the PLQY of half-constructed devices led to effective selection of materials. A schematic of the final device stack and a scanning electron microscopy (SEM) cross-sectional image are shown in FIG. 3a,b. Higher current densities were observed in E+G NC-LEDs, and significantly improved EQEs (FIG. 3c,d). A peak EQE of 20.3% at ˜0.1 mAcm⁻² current density and ˜620 nm emission wavelength was measured, placing red perovskite LEDs in the same quantum efficiency range as commercial OLEDs. Considering the PLQY of isolated perovskite NC films on glass, the refractive indices of the perovskite layer, optical outcoupling, and photon recycling, an internal PLQY of 0.88 was estimated as discussed in methods above.

The most pressing challenge for red-emitting metal halide perovskites is achieving band gap stability. In FIG. 3f,g, it is shown that the emission spectra for LEDs operate at a fixed current density over time and over a range of current densities, respectively. For the neat NC-LEDs held at a constant current density of 1.5 mAcm⁻² measured over 20 minutes, a broadening of the emission peak and the emergence of a shoulder at ˜680 nm was observed. Also observed was a similar broadening and the emergence of a shoulder when these LEDs are measured at increasing current densities. These observations are consistent with halide segregation driven by electrical biasing/current injection during LED operation and causing lower energy emission from iodide enriched regions. In contrast, the emission spectrum for the E+G NC-LEDs is stable at 620 nm under the same operating conditions and duration.

Understanding the origin of this improved device performance requires identifying the key ligand-perovskite interactions that stabilise the surface. To this end, solid-state ¹³C NMR of the OA/OLA-capped NCs was performed before and after the E+G treatment. The resulting data, FIG. 4a, 4b, show a clear peak at 130.2 ppm, which arises from the double-bonded carbons in the OA/OLA molecules. The presence of this peak, alongside the aliphatic —CH₂-peaks (30-27 ppm), clearly signifies the existence of OA/OLA on the NC surface even after the EDTA, GL or E+G ligand treatment; these remaining nonpolar OA/OLA chains likely ensure NC solubility in toluene after the ligand treatment. The absence of EDTA peaks from the EDTA-treated sample shows that the amount of EDTA on the NC surface is below the NMR detection limit, while clear GL peaks arising from the carbonyl and α-carbonyl environments confirm their presence. The peak at 38 ppm suggests the presence of oxidised GL, which may indicate that reduction of some species on the perovskite surface may be part of the active role of GL. A key function of GL and EDTA ligands can be inferred from their Pb binding ability: both ligands are known to bind strongly to Pb atoms, shown through solution-state NMR (FIG. 4c, details in the method section above).

The proposed molecular interactions of the E+G ligands with Pb²⁺ on the NC surface is shown in FIG. 4d. It is postulated that part of the role of EDTA and GL is to remove undercoordinated lead from the NC surface, resulting in an electronically “cleaner”, less defective surface. This “stripping” action is consistent with (i) reduction in NC sizes, (ii) existence of Pb-ligand complexes in solution, and (iii) large binding energy of EDTA and GL to Pb atoms. Some of the excess ligands in the treatment may then bind to the remaining Pb on the “cleaned” perovskite surface, further decreasing the defect concentration.

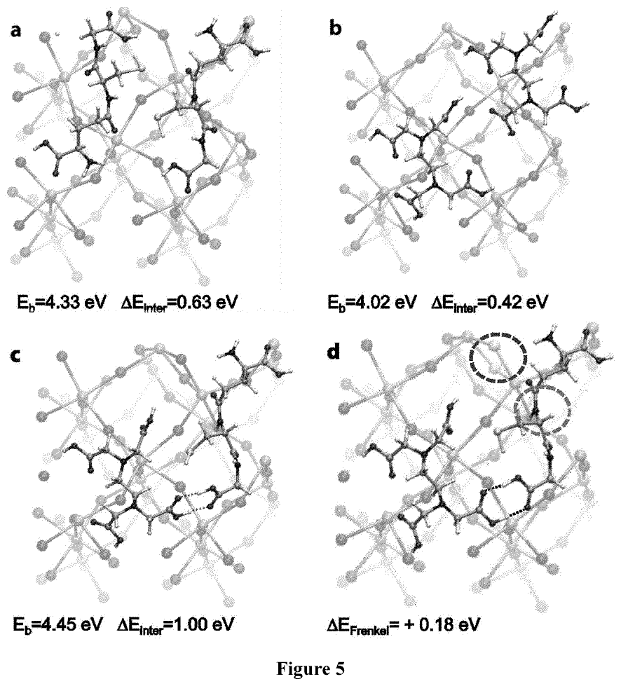

To gain further understanding of ligand binding, the interaction of GL and EDTA with the surface of MAPbI₃ was modelled using DFT (FIG. 5). A PbI₂-terminated surface representative of an unpassivated perovskite surface with exposed, undercoordinated Pb atoms was considered. GL and EDTA were decomposed into their possible binding moieties and calculated the binding energy (BE) of each ligand to the perovskite. The binding energy is defined as BE=E_{lig@surface}−E_{lig}−E_{surface}, where the latter three terms are the energy of the surface and bound ligand, the energy of the isolated ligand, and the energy of the bare surface, respectively. The calculated BE for GL is −1.85 eV, which is large compared to the calculated value of −0.58 eV for acetic acid or −0.84 eV for methylamine, representative of carboxylic acid and primary amine binding moieties of GL. It was deduced that the large BE is due to contributions from multiple binding moieties. A large BE for EDTA (−1.60 eV) was determined, slightly lower than that of GL, with steric hindrance limiting binding from the tertiary aminic group; this is also consistent with the observation of only GL in the ¹³C solid-state NMR spectra of E+G NCs (FIG. 4a).

Further evaluated was the BE of two interacting GL molecules, two interacting EDTA molecules, and an interacting E+G pair of molecules on the perovskite surface (FIG. 5). The E+G pair has the highest binding energy, enhanced by a synergistic effect between GL and EDTA; intermolecular hydrogen bonding between carboxylic groups of GL and EDTA provides extra stabilisation to these surface adsorbed molecules, leading to a BE of −4.45 eV.

The calculations confirm that this specific pairing of ligands leads to a strong affinity with the perovskite surface. Also assessed was how this influences the migration of halide species. Iodine Frenkel defects, which are iodide interstitial-vacancy pairs, are the most energetically probable defects at the PbI₂-terminated perovskite surface, with shallow formation energy (0.03 eV). It was calculated that the formation energy of an iodine Frenkel defect at the PbI₂-terminated perovskite surface in the presence of GL, E+G, or without passivating molecules, details in the methods section above. It was found that GL surface passivation raises the iodine Frenkel defect formation energy to 0.15 eV, while E+G further increases the formation energy to 0.18 eV. This is significantly higher than calculated values for other passivating agents. For example, in the presence of polyethylene oxide, the formation of an interstitial iodine defect becomes less favourable by 0.08 eV compared to bare perovskite surface. To summarise, the high calculated binding energy, coupled with the significant increase in the iodide Frenkel defect formation energy, suggests that the GL and the combination of E+G ligands significantly inhibits undercoordinated Pb atoms from stabilising these Frenkel defects. Since halide Frenkel defects are expected to be the ionic species responsible for halide segregation under illumination or device operation, the results are consistent with suppressed defect formation suppressing halide segregation in E+G treated NCs.

Conclusion

It has been demonstrated that a lead-complexing multidentate ligand treatment leads to bandgap-stable red electroluminescence from mixed halide perovskite NC-LEDs, with a peak EQE at 620 nm surpassing 20%. Stripping the NC surface of defects is part of the active role of the ligands. Furthermore, it has been shown that both ligand-ligand and ligand-surface interactions are important for achieving a stable ligand shell on the NC surface, and the multidentate ligand interactions with the surface greatly suppress surface defect formation. Beyond light emission, these findings are broadly applicable to stabilising the bandgap of mixed-ion metal halide perovskites for a range of applications, including multi-junction photovoltaics, and will enable perovskites to deliver upon the promise of being remarkably versatile and tuneable semiconductors.

### Example 2—Treatment of Polycrystalline Perovskite

### Experimental Description

I. Preparation of FA_{0.83}Cs_{0.17}Pb(I_{0.9}Br_{0.1})₃ perovskite films

Microscope glass slides were cut into approximately 25 mm by 25 mm square pieces. The glass substrates were subsequently cleaned via sonication in Decon 90 (1 vol %), deionized water, acetone, and isopropanol for 10 minutes each. The glass substrates were dried with N₂ and oxygen-plasma-treated for 10 minutes. The quartz substrates were cleaned with the same procedure.

1.45M of perovskite precursor of the composition FA_{0.83}Cs_{0.17}Pb(I_{0.9}Br_{0.1})₃ was made by dissolving 206.97 mg FAI, 64.04 mg CsI, 568.20 mg PbI₂, and 79.83 mg PbBr₂ in 1 mL of a mixed solvent of 4:1 volume ration of DMF:DMSO. 35 μL of precursor solution was spread onto the glass substrate or quartz and spun at 1,000 rpm for 10 seconds, and then at 6,000 rpm for 35 seconds. 100 μL of anisole was dropped onto the substrates 10 seconds before the end of the spin-coating program. The perovskite films were then annealed at 100° C. for 15 minutes on a hotplate in a nitrogen glove box.

II. Preparation of EDTA Solution

0.067 Molar EDTA solutions were made by stirring EDTA in toluene or chlorobenzene either with or without butylamine (0.067 M) at 60° C. overnight. The undissolved EDTA powder was filtered out with a 0.45 μm filter before use.

Perovskite films were soaked in the EDTA/toluene solution for different amounts of time. Subsequently, the films were dipped in pure toluene for 10 seconds each to rinse of the access EDTA. The films were immediately blowed dry with a N₂ gun and left in a clean dry box for further testing.

Results and Discussion

I. Effect of Rinsing Time on Films

As the soaking time for perovskite films increase, the surfaces of the films transition from a smooth shiny appearance to a matt appear to the eye. This is indicative of increased light scattering at the surface of the film resulting from a rougher surface. The photoluminescence quantum efficiency (PLQE) of the perovskite films increased within the first three seconds of soaking in EDTA solution. Then the increase in PLQE levels off as the films are soaked for longer times (FIG. 6). This indicates that the EDTA rinsing has etched away some of the surface of the perovskite thin films, and resulted in improved electronic quality of the surface of the films.

II. Comparison of Toluene and Chlorobenzene Solvents

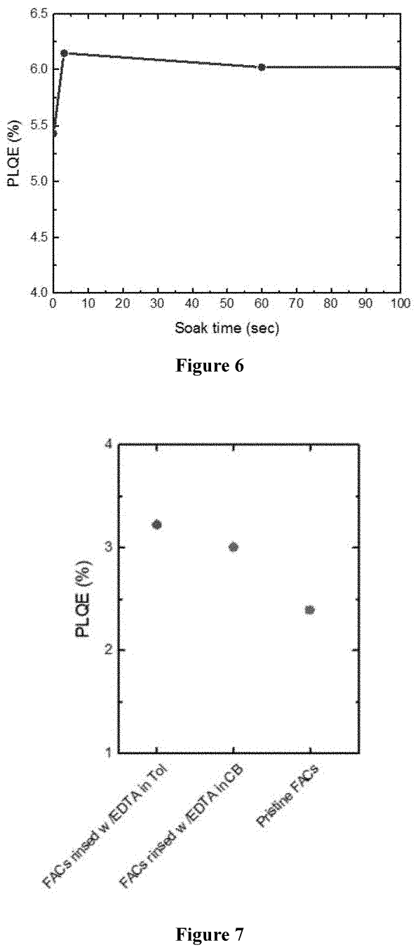

Other potential solvents were explored for dissolving EDTA better without dissolving the perovskite film. While toluene and chlorobenzene have very low solubility for EDTA, they were less detrimental to the perovskite films. Films rinsed in both toluene and chlorobenzene solutions had similar improvement in PLQE (FIG. 7).

III. Rinsing with Neat Toluene

UV-vis absorption was done on solution-treated films. As a comparison, pristine FACs films were rinsed with neat toluene for the same amount of time, and it did not exhibit the same absorbance drop as the films treated with EDTA solution and subsequent toluene rinse. This shows that the thickness of the perovskite film decreased as EDTA etches away the access PbI₂ at the surface. The UV-vis spectra of FACs in neat toluene rinse compared to FACs in EDTA and toluene rinse shows that toluene alone does not etch the perovskite surface.

1. A process for chemically etching the surface of a metal halide perovskite, the process comprising treating the metal halide perovskite with one or more multidentate ligands,
wherein the one or more multidentate ligands comprise an organic compound or a salt thereof, which organic compound comprises three or more binding groups.

2. A process according to claim 1, wherein the organic compound is suitable for binding to Pb²⁺.

3. A process according to claim 1, wherein the organic compound has a molecular weight of no greater than 1000 gmol⁻¹, preferably no greater than 500 gmol⁻¹.

4. A process according to claim 1, wherein the one or more multidentate ligands comprise an organic compound or a salt thereof, which organic compound comprises two or more carboxylic acid groups,
preferably wherein the organic compound comprises three or more carboxylic acid groups.

5. A process according claim 1, wherein the one or more multidentate ligands comprise an organic compound or a salt thereof, which organic compound comprises (a) two or more carboxylic acid groups and (b) one or more amine groups or one or more thiol groups,
preferably wherein the organic compound comprises (a) two or more carboxylic acid groups and (b) one or more amine groups.

6. A process according to claim 1, wherein the one or more multidentate ligands comprise one or more organic compounds selected from ethylenediaminetetracetic acid (EDTA), glutathione reduced (GL), glutathione oxidised, iminodiacetic acid (IDA), N-methyliminodiacetic acid, 1,6-diaminohexanetetracetic acid, iminodisuccinic acid (IDS), nitrilotriacetic acid (NTA), diethylenetriaminepentaacetic acid (DTPA), ethylene glycol-bis(2-aminoethylether)-N,N,N′,N′-tetraacetic acid (EGTA), 1,2-bis(o-aminophenoxy)ethane-N,N,N′,N′-tetraacetic acid (BAPTA), (1,4,7-triazacyclononane-1,4,7-triyl)triacetic acid (NOTA), 1,4,7,10-tetraazacyclododecane-1,4,7,10-tetraacetic acid (DOTA), 1,2-bis(2-aminophenoxy)ethane-N,N,N′,N′-tetraacetic acid, trans-1,2-diaminocyclohexane-N,N,N′,N′-tetraacetic acid, 1,3-diamino-2-hydroxypropane-N,N,N′,N′-tetraacetic acid, 1,2-diaminopropane-N,N,N′,N′-tetraacetic acid, ethylenediamine-N,N′-diacetic acid, ethylenediaminetetrapropionic acid, N-(2-hydroxyethyl) ethylenediaminetriacetic acid, N-(2-hydroxyethyl)ethylenediamine-N,N′,N′-triacetic acid, N,N,N′,N′-tetrakis(2-hydroxyethyl)ethylenediamine, triethylenetetramine-N,N,N′,N″,N′″,N′″-hexaacetic acid, 1,3-diamino-2-propanol-N,N,N′,N′-tetraacetic acid, N-(2-hydroxyethyl)ethylenediamine-N,N′,N′-triacetic acid, trans-1,2-cyclohexanediaminetetraacetic acid, nicotianamine, ethylenediamine-N,N′-disuccinic acid (EDDS), ethylenediamine-N,N′-bis(2-hydroxyphenylacetic acid) (EDDHA), methylglycinediacetic acid (MGDA), dimercaprol, dimercaptosuccinic acid (DMSA) penicillamine (Pen), cysteine (Cys), desferrioxamine B (DFB), desferricoprogen (DFC), N,N′-bis[(6-carboxy-2-pyridyl)methyl]-4,13-diaza-18-crown-6, N-phenylthio-benzohydroxamic acid, alanyl-cysteine (AlaCys), cysteinyl-glycine (CysGly), a compound of formula HO(CH₃)NCO(CH₂)ₓCONH(CH₂)_{y}CON(CH₃)OH where x=2 or 3, y=2 to 5, and salts thereof,
preferably wherein the one or more multidentate ligands comprise one or more organic compounds selected from ethylenediaminetetracetic acid (EDTA), glutathione reduced (GL) and salts thereof.

7. A process according to claim 1, wherein the one or more multidentate ligands comprise:
(i) a first organic compound or a salt thereof, which first organic compound comprises two or more carboxylic acid groups; and
(ii) a second organic compound or a salt thereof, which second organic compound comprises two or more carboxylic acid groups, one or more amine groups and one or more thiol groups.

8. A process according to claim 1, wherein the one or multidentate ligands comprise (i) ethylenediaminetetracetic acid (EDTA) or a salt thereof and (ii) glutathione reduced (GL) or a salt thereof.

9. A process according to claim 1, wherein (a) the metal halide perovskite is present in a composition which composition further comprises a passivating agent or (b) the process further comprises treating the metal halide perovskite with a passivating agent,
preferably wherein the passivating agent is a compound comprising an amine group or a carboxylic acid group, or a salt thereof,
more preferably wherein the passivating agent is a primary amine of formula R—NH₂ wherein R is a C₈₋₂₄ alkyl or C₈₋₂₄ alkenyl group, or a salt thereof.

10. A process according to claim 1, wherein treating the metal halide perovskite with the one or more multidentate ligands comprises contacting the metal halide perovskite with the one or more multidentate ligands in the presence of a solvent.

11. A process according to claim 10, wherein the solvent is a non-polar solvent,
preferably wherein the solvent is a non-polar aprotic solvent,
more preferably wherein the solvent comprises benzene, toluene, chlorobenzene, anisole, methyl acetate, ethyl acetate or diethyl ether.

12. A process according to claim 1, wherein the process further comprises rinsing the metal halide perovskite with a rinsing solvent after treatment with the one or more multidentate ligands,
preferably wherein the rinsing solvent is a non-polar aprotic solvent,
more preferably wherein the rinsing solvent comprises benzene, toluene, chlorobenzene, anisole, methyl acetate, ethyl acetate or diethyl ether.

13. A process according to claim 1, wherein the metal halide perovskite comprises a metal halide perovskite of formula (I):
[A][M][X]₃ (I)
wherein:
[A] comprises one or more first cations;
[M] comprises one or more metal dications; and
[X] comprises one or more halide anions.

14. A process according to claim 1, wherein:
the metal halide perovskite comprises lead or tin, preferably wherein the metal halide perovskite comprises lead; and/or
the metal halide perovskite comprises iodide and bromine.

15. A process according to claim 1, wherein the metal halide perovskite comprises a metal halide perovskite which is (CH₃NH₃)Pb(Br_{y}I_{(1-y)})₃ or Csₓ(H₂N—C(H)═NH₂)₍₁₋ₓ₎Pb(Br_{y}I_{(1-y)})₃, where x is from 0.0 to 1.0 and y is from 0.0 to 1.0, preferably wherein y is from 0.01 to 0.99.

16. A process according to claim 1, wherein the process comprises treating a composition comprising a metal halide perovskite with the one or more multidentate ligands, which composition comprises:
(i) particles comprising the metal halide perovskite;
(ii) a polycrystalline form of the metal halide perovskite; or
(iii) a single crystal of the metal halide perovskite,
preferably wherein the composition comprises particles comprising the metal halide perovskite,
more preferably wherein the composition comprises nanoparticles comprising the metal halide perovskite.

17. A process according to claim 1, wherein the process produces a modified metal halide perovskite, and wherein:
the modified metal halide perovskite has an increased luminescence efficiency relative to the metal halide perovskite prior to treatment; and/or
the modified metal halide perovskite has a reduced thickness or a reduced particle or crystal size relative to the metal halide perovskite prior to treatment.

18. A chemically etched metal halide perovskite obtainable by the process for chemically etching the surface of a metal halide perovskite as defined in claim 1.

19. A process for producing a semiconductor device comprising a metal halide perovskite, the process comprising a process for chemically etching the surface of a metal halide perovskite as defined in claim 1.

20. A process according to claim 19, wherein the semiconductor device is an optoelectronic device,
preferably wherein the optoelectronic device is a light emitting device or a photovoltaic device,
more preferably wherein the optoelectronic device is a light emitting device.

21. A composition comprising a metal halide perovskite and one or more multidentate ligands,
wherein the one or more multidentate ligands comprise an organic compound or a salt thereof, which organic compound comprises three or more binding groups, which three or more binding groups comprise two or more carboxylic acid groups.

22. A composition according to claim 21, wherein the composition comprises nanoparticles comprising the metal halide perovskite.

23. A composition according to claim 21, wherein organic compound comprises one or more thiol groups,
preferably wherein the one or more multidentate ligands are as defined in any one of claims 3 to 8.

24. A semiconductor device comprising a composition as defined in claim 21.

25. A semiconductor device according to claim 23, wherein the semiconductor device is an optoelectronic device,
preferably wherein the semiconductor device is a light emitting device,
more preferably where the light emitting device has a photoluminescence peak of from 615 nm to 640 nm.
